(19) United States
(12) Patent Application Publication
(10) Pub. No.: US 2025/0326956 A1
(43) Pub. Date: Oct. 23, 2025

(54) RESIN COMPOSITION, ADHESIVE MEMBER, AND DISPLAY DEVICE INCLUDING THE ADHESIVE MEMBER

(71) Applicant: Samsung Display Co., Ltd., Yongin-si (KR)

(72) Inventor: Yosuke SAITO, Yokohama (JP)

(21) Appl. No.: 19/186,101

(22) Filed: Apr. 22, 2025

(30) Foreign Application Priority Data
Apr. 23, 2024 (KR) 10-2024-0053806

(51) Int. Cl. C09J 109/00; C08F 36/06; C08F 36/16; H05K 5/00; H05K 5/03

(52) U.S. Cl. CPC C09J 109/00; C08F 36/06; C08F 36/16; H05K 5/0018; H05K 5/03; C09J 2409/00

(57) ABSTRACT

A resin composition is disclosed. The resin composition may include a polybutadiene having an unsaturated bond in at least one selected from among a main chain and a side chain, at least one photoinitiator, at least one monofunctional (meth)acrylate monomer, and/or at least one (meth)acrylate oligomer. The resin composition may not include a urethane (meth)acrylate-terminated polybutadiene. An amount of the polybutadiene may be about 1 wt % or more and less than about 10 wt % based on a total of 100 wt % of the resin composition. The resin composition may have a shear viscosity of about 8 mPa·s to about 50 mPa·s as measured at a temperature of about 25° C. The resin composition may have a tensile modulus of about 10 MPa to about 900 MPa at a temperature of about 25° C. after photocuring.

### CROSS-REFERENCE TO RELATED APPLICATION

The present application claims priority to and the benefit of Korean Patent Application No. 10-2024-0053806, filed on Apr. 23, 2024, in the Korean Intellectual Property Office, the entire disclosure of which is incorporated herein by reference.

### BACKGROUND

### 1. Field

One or more embodiments of the present disclosure relate to a resin composition including a polybutadiene, an adhesive member made or provided from the resin composition, and a display device (e.g., an electronic device) including the adhesive member.

### 2. Related Art

One or more display devices used in multimedia apparatuses, such as televisions, mobile phones, tablet computers, navigation units, game consoles, and/or the like, have been developed. A display device may include one or more suitable components constituting the display device, and an adhesive member may be provided between the components. The adhesive member may be made from a resin composition, and it is desirable for the adhesive member included in the display device to have characteristics of stably coupling the components of the display device to each other and preventing display quality from being reduced.

### SUMMARY

One or more aspects of embodiments of the present disclosure are directed toward a resin composition which exhibits a low-viscosity characteristic before curing and/or exhibits excellent or suitable impact resistance, excellent or suitable reliability of adhesion, and/or excellent or suitable light fastness after curing, an adhesive member made or provided from the resin composition, and a display device (e.g., an electronic device) including the adhesive member.

Additional aspects of embodiments will be set forth in part in the description which follows and, in part, will be apparent from the description, or may be learned by practice of the presented embodiments of the disclosure.

One or more embodiments of the present disclosure provide a resin composition which may include a polybutadiene having an unsaturated bond (e.g., a double bond between carbon atoms) in at least one selected from among a main chain and a side chain, at least one photoinitiator, at least one monofunctional (meth)acrylate monomer, and/or at least one (meth)acrylate oligomer and may not include a urethane (meth)acrylate-terminated polybutadiene. An amount of the polybutadiene may be about 1 wt % or more and less than about 10 wt % based on a total of 100 wt % of the resin composition, and the resin composition may have a shear viscosity of about 8 mPa·s to about 50 mPa·s as measured at a temperature of about 25° C. according to JIS Z8803 method and may have a tensile modulus of about 10 MPa to about 900 MPa at a temperature of about 25° C. after photocuring.

In one or more embodiments, the resin composition may have a 180° peel strength of about 500 gf/25 mm or more for at least one selected from among a glass substrate and a polymer substrate at the temperature of about 25° C. after the photocuring.

In one or more embodiments, the resin composition may have a yellow index (YI) of about 1 or less after a light fastness test according to DIN75220 method after the photocuring.

In one or more embodiments, the polybutadiene may include a moiety represented by Formula 1 below:

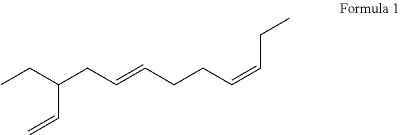

In one or more embodiments, the monofunctional (meth)acrylate monomer may include at least one selected from among 4-hydroxybutyl acrylate (4-HBA), isobornyl acrylate (IBXA), and isodecyl acrylate (IDAA).

In one or more embodiments, an amount of the monofunctional (meth)acrylate monomer may be about 82 wt % or more and less than about 92 wt % based on a total of 100 wt % of the resin composition.

In one or more embodiments, the photoinitiator may include a radical polymerization initiator.

In one or more embodiments, the resin composition may be provided by an inkjet printing method and/or a dispensing method.

One or more embodiments of the present disclosure provide an adhesive member which may include a polymer derived from a resin composition and may have a tensile modulus of about 10 MPa to about 900 MPa at a temperature of about 25° C. The resin composition may include a polybutadiene having an unsaturated bond (e.g., a double bond between carbon atoms) in at least one selected from among a main chain and a side chain, at least one photoinitiator, at least one monofunctional (meth)acrylate monomer, and/or at least one (meth)acrylate oligomer and may not include a urethane (meth)acrylate-terminated polybutadiene. An amount of the polybutadiene may be about 1 wt % or more and less than about 10 wt % based on a total of 100 wt % of the resin composition, and the resin composition may have a shear viscosity of about 8 mPa·s to about 50 mPa·s as measured at a temperature of about 25° C. according to JIS Z8803 method.

In one or more embodiments, the adhesive member may have a 180° peel strength of about 500 gf/25 mm or more for at least one selected from among a glass substrate and a polymer substrate at the temperature of about 25° C.

In one or more embodiments, the adhesive member may have a yellow index (YI) of about 1 or less after a light fastness test according to DIN 75220 method.

In one or more embodiments, the polybutadiene may include a moiety represented by Formula 1 below:

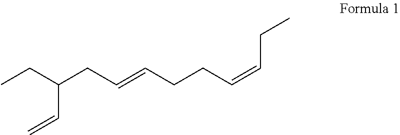

In one or more embodiments, the monofunctional (meth)acrylate monomer may include at least one selected from among 4-hydroxybutyl acrylate (4-HBA), isobornyl acrylate (IBXA), and isodecyl acrylate (IDAA).

One or more embodiments of the present disclosure provide an electronic device which may include a display panel, a window on the display panel, and/or an adhesive member, which may include a polymer derived from a resin composition having a shear viscosity of about 8 mPa·s to about 50 mPa·s as measured at a temperature of about 25° C. according to JIS Z8803 method and which may be between the display panel and the window. The adhesive member may have a tensile modulus of about 10 MPa to about 900 MPa at a temperature of about 25° C. The resin composition may include a polybutadiene having an unsaturated bond (e.g., a double bond between carbon atoms) in at least one selected from among a main chain and a side chain, at least one photoinitiator, at least one monofunctional (meth)acrylate monomer, and/or at least one (meth)acrylate oligomer and may not include a urethane (meth)acrylate-terminated polybutadiene. An amount of the polybutadiene may be about 1 wt % or more and less than about 10 wt % based on a total of 100 wt % of the resin composition.

In one or more embodiments, the adhesive member may have a 180° peel strength of about 500 gf/25 mm or more for at least one selected from among a glass substrate and a polymer substrate at the temperature of about 25° C.

In one or more embodiments, the adhesive member may have a yellow index (YI) of about 1 or less after a light fastness test according to DIN75220 method.

In one or more embodiments, the monofunctional (meth)acrylate monomer may include at least one selected from among 4-hydroxybutyl acrylate (4-HBA), isobornyl acrylate (IBXA), and isodecyl acrylate (IDAA).

In one or more embodiments, the display panel may be foldable around at least one folding axis.

In one or more embodiments, the electronic device may further include a light control layer between the adhesive member and the window and an optical adhesive layer between the light control layer and the window, and the optical adhesive layer may include a polymer derived or provided from the resin composition.

In one or more embodiments, the electronic device may further include an input sensing part between the display panel and the window, and the adhesive member may be between the display panel and the input sensing part and/or between the input sensing part and the window.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1A is a perspective view illustrating a display device according to one or more embodiments;

FIG. 1B is a perspective view illustrating a display device according to one or more embodiments;

FIG. 1C is a plan view illustrating a display device according to one or more embodiments;

FIG. 1D is a perspective view illustrating a display device according to one or more embodiments;

FIG. 2 is an exploded perspective view illustrating a display device according to one or more embodiments;

FIG. 3 is a cross-sectional view illustrating a portion corresponding to line I-I′ in FIG. 2;

FIG. 4 is a cross-sectional view illustrating a portion of a display device according to one or more embodiments;

FIG. 5A is a schematic view illustrating a method for manufacturing an adhesive member according to one or more embodiments;

FIG. 5B is a schematic view illustrating a method for manufacturing an adhesive member according to one or more embodiments;

FIG. 5C is a schematic view illustrating a method for manufacturing an adhesive member according to one or more embodiments;

FIG. 5D is a schematic view illustrating a method for manufacturing an adhesive member according to one or more embodiments;

FIG. 6A is a schematic view illustrating a method for manufacturing an adhesive member according to one or more embodiments;

FIG. 6B is a schematic view illustrating a method for manufacturing an adhesive member according to one or more embodiments;

FIG. 6C is a schematic view illustrating a method for manufacturing an adhesive member according to one or more embodiments;

FIG. 7 is a cross-sectional view illustrating a display device according to one or more embodiments; and

FIG. 8 is a cross-sectional view illustrating a display device according to one or more embodiments.

### DETAILED DESCRIPTION

The subject matter of the present disclosure may be modified in one or more suitable forms, and particular embodiments thereof will be illustrated in the drawings and described herein in more detail. The subject matter of the present disclosure should not be construed as limited to one or more embodiments set forth herein. Rather, these embodiments are provided as examples so that this disclosure will be thorough and complete, and will fully convey the aspects and features of embodiments of the present disclosure to those skilled in the art.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure.”

In the context of the present disclosure and unless otherwise defined, the terms “use,” “using,” and “used” may be considered synonymous with the terms “utilize,” “utilizing,” and “utilized,” respectively.

As utilized herein, the term “about” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, 20%, 10%, or 5% of the stated value.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend the present disclosure, including the appended claims, to expressly recite any sub-range subsumed within the ranges expressly recited herein. It will be understood that if (e.g., when) an element (e.g., a region, a layer, a section, and/or the like) is referred to as being “on”, “connected to”, or “coupled to” another element, it may be directly on, connected or coupled to the other element or a third element may be between the elements. If (e.g., when) an element is referred to as being “directly on” another element, there are no intervening elements present.

Like reference numbers or symbols refer to like elements throughout. In one or more embodiments, in the drawings, the thickness, the ratio, and the dimension of elements are exaggerated for effective description of the technical contents. The term “and/or” includes one or more combinations which may be defined by relevant elements.

In one or more embodiments, unless otherwise specified, “A or B” refers to “including A, including B, or including A and B.”

As used herein, “combination thereof” refers to a mixture of constituents, a stack, a composite, a copolymer, an alloy, a blend, and/or a reaction product.

It will be understood that, although the terms first, second, and/or the like may be used herein to describe one or more suitable elements, these elements should not be limited by these terms. These terms are only used to distinguish one element from another element. For example, a first element may be termed a second element without departing from the spirit and scope of the present disclosure, and similarly, a second element may be termed a first element. As used herein, the singular forms are intended to include the plural forms as well, unless the context clearly indicates otherwise.

In one or more embodiments, the terms, such as “below”, “beneath”, “on” and “above”, are used to illustrate the relation of elements shown in the drawings. The terms are relative concept and are illustrated based on the direction shown in the drawing.

It will be further understood that the terms such as “includes” or “has”, if (e.g., when) used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have substantially the same meaning as generally understood by one of ordinary skill in the art to which this disclosure belongs. It will be further understood that terms, such as those defined in generally used dictionaries, should be interpreted as having a meaning that is consistent with their meaning in the context of the relevant art and/or the present specification and should not be interpreted in an idealized or overly formal sense unless expressly so defined herein.

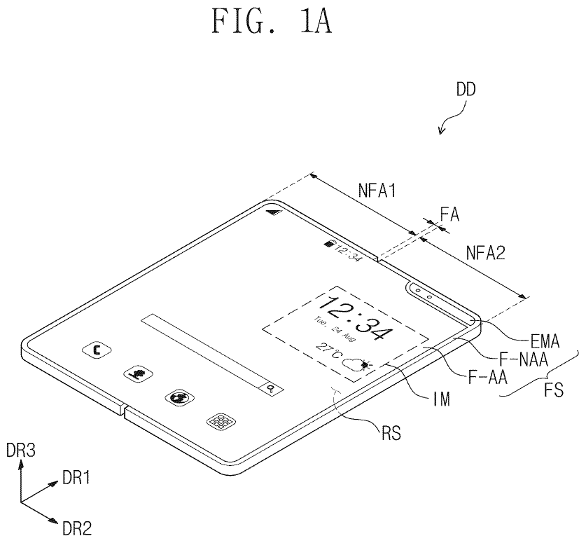

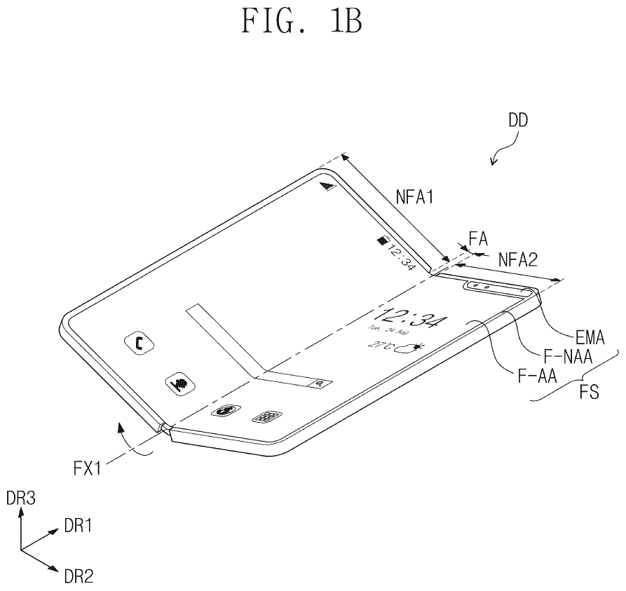

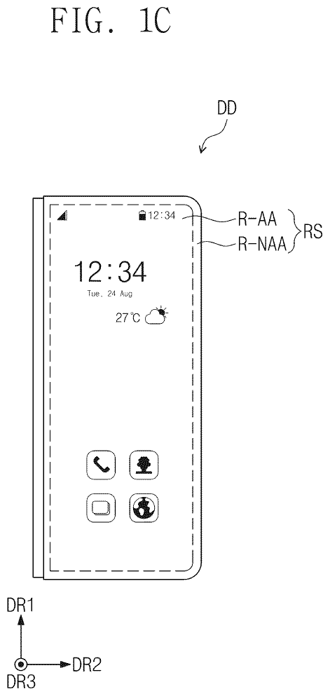

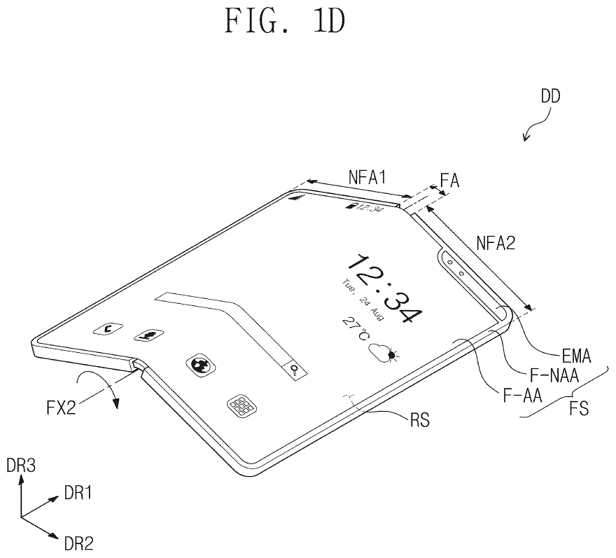

Hereinafter, an adhesive member and a display device (e.g., an electronic device) including the adhesive member according to one or more embodiments of the present disclosure will be described with reference to the accompanying drawings. FIG. 1A is a perspective view illustrating a spread state of a display device DD according to one or more embodiments.

In one or more embodiments, the display device DD may be a device that may be activated in response to an electrical signal. For example, the display device DD may be a mobile phone, a tablet computer, a vehicle navigation unit, a game console, a wearable device, and/or the like, but embodiments of the present disclosure are not limited thereto. FIG. 1A is a perspective view illustrating a mobile phone as an example of the display device DD. In the present disclosure, an electronic device may be the display device DD or may include the display device DD.

The display device DD may include a first display surface FS defined by a first directional axis DR1 and a second directional axis DR2 crossing the first directional axis DR1. The display device DD may provide an image IM for a user through the first display surface FS. The image IM may include not only a dynamic image but also a still image. The display device DD may display the image IM in a third directional axis DR3 through the first display surface IM substantially parallel to each of the first directional axis DR1 and the second directional axis DR2.

In one or more embodiments, the first directional axis DR1 and the second directional axis DR2 may normal (e.g., substantially perpendicular) cross each other, and the third directional axis DR3 may be a normal (e.g., a substantially perpendicular) direction to a plane defined by the first directional axis DR1 and the second directional axis DR2. A thickness direction of the display device DD may be a direction substantially parallel to the third directional axis DR3. A front surface (or top surface) and a rear surface (or bottom surface) may oppose each other with respect to the third directional axis DR3, and a normal (e.g., substantially perpendicular) direction to each of the front surface (or top surface) and the rear surface (or bottom surface) may be substantially parallel to the third directional axis DR3. The front surface (or top surface) refers to a surface substantially adjacent to the first display surface FS, and the rear surface (or bottom surface) refers to a surface spaced and/or apart (e.g., spaced apart or separated) from the first display surface FS. In one or more embodiments, the rear surface (or bottom surface) refers to a surface substantially close to a second display surface RS to be further described herein. An upper side refers to a direction that may be substantially close to the first display surface FS, and a lower side refers to a direction that may be substantially away from the first display surface FS.

A cross-section refers to a surface substantially parallel to a thickness direction DR3, and a plane refers to a surface normal (e.g., substantially perpendicular) to the thickness direction DR3. The plane refers to a plane defined by the first directional axis DR1 and the second directional axis DR2.

Directions indicated by the first to third directional axes DR1, DR2, and DR3 used herein are relative concepts and may be suitably adjusted or changed to other directions. In one or more embodiments, the directions indicated by the first to third directional axes DR1, DR2, and DR3 may be referred to as first to third directions and may be designated by like reference numbers or symbols.

The display device DD may detect an external input applied from the outside. The external input may include one or more suitable types or kinds of inputs provided from the outside of the display device DD. For example, the external input may include not only a touch by part of the body, such as a user's hand, but also an external input (e.g., hovering) applied by approaching the display device DD or being substantially adjacent thereto by a set or predetermined distance. In one or more embodiments, the external input may include one or more suitable types or kinds, such as force, pressure, temperature, and/or light.

The display device DD may include the first display surface FS and the second display surface RS. The first display surface FS may include a first active area F-AA, a first peripheral area F-NAA, and/or an electronic module area EMA. The second display surface RS may be defined as a surface opposing at least a portion of the first display surface FS. For example, the second display surface RS may be defined as one portion of a rear surface of the display device DD.

The first active area F-AA may be an area that is activated in response to an electrical signal. The first active area F-AA may be an area on which the image IM is displayed, and which may detect one or more suitable types or kinds of external inputs.

The first peripheral area F-NAA may be substantially adjacent to the first active area F-AA. The first peripheral area F-NAA may have a set or predetermined color. The first peripheral area F-NAA may surround the first active area F-AA. In one or more embodiments, a shape of the first active area F-AA may be substantially defined by the first peripheral area F-NAA. However, this is illustrative, and the first peripheral area F-NAA may be substantially adjacent to only one side of the first active area F-AA, or may not be provided.

One or more suitable electronic modules may be on the electronic module area EMA. For example, the electronic modules may include at least one selected from among a camera, a speaker, a light detecting sensor, and a heat detecting sensor. The electronic module area EMA may detect an external subject received through the display surfaces FS and RS and/or may provide a sound signal, such as voice, to the outside through the display surfaces FS and RS. The electronic module may include a plurality of components, and is not limited to one or more embodiments as described.

The electronic module area EMA may be surrounded by the first peripheral area F-NAA. However, this is illustrative, and the electronic module area EMA is not limited to one or more embodiments as described. For example, the electronic module area EMA may be surrounded by the first active area F-AA and the first peripheral area F-NAA, and the electronic module area EMA may be within the first active area F-AA.

In one or more embodiments, the display device DD may be a flexible display device. The display device DD according to one or more embodiments may include at least one folding area FA and a plurality of non-folding areas NFA1 and NFA2 each extending from the folding area FA. For example, a first non-folding area NFA1, the folding area FA, and a second non-folding area NFA2 may be defined in a second direction DR2. In one or more embodiments, the display device DD may include the first non-folding area NFA1 and the second non-folding area NFA2 which may be spaced and/or apart (e.g., spaced apart or separated) from each other in the second direction DR2 with the folding area FA therebetween. For example, the first non-folding area NFA1 may be at one side of the folding area FA in the second direction DR2, and the second non-folding area NFA2 may be at the other side of the folding area FA in the second direction DR2.

FIG. 1A is a perspective view illustrating a display device DD including one folding area FA. However, embodiments of the present disclosure are not limited thereto, and a plurality of folding areas may be defined in the display device DD. For example, the display device according to one or more embodiments may include two or more folding areas and three or more non-folding areas with each of the folding areas therebetween.

FIG. 1B is a perspective view illustrating a folding operation of a display device DD according to one or more embodiments. FIG. 1C is a plan view illustrating a folded state of the display device DD according to one or more embodiments. FIG. 1D is a perspective view illustrating a folding operation of a display device DD according to one or more embodiments.

Referring to FIG. 1B, the display device DD according to one or more embodiments may be folded around a first folding axis FX1 extending in the first direction DR1. In a state in which the display device DD is folded, the folding area FA may have a set or predetermined curvature and/or a set or predetermined radius of curvature. The display device DD may be folded around the first folding axis FX1 to be changed into an in-folded state so that the first non-folding area NFA1 and the second non-folding area NFA2 face each other, and the first display surface FS may not be exposed to the outside.

Referring to FIG. 1C, in the display device DD according to one or more embodiments, the second display surface RS may be visible to a user in the in-folded state. In one or more embodiments, the second display surface RS may include a second active area R-AA that displays an image. The second active area R-AA may be an area that is activated in response to an electrical signal. The second active area R-AA may be an area on which an image is displayed, and which may detect one or more suitable types or kinds of external inputs.

The second peripheral area R-NAA may be substantially adjacent to the second active area R-AA. The second peripheral area R-NAA may have a set or predetermined color. The second peripheral area R-NAA may surround the second active area R-AA. The second display surface RS of the display device DD may also further include an electronic module area on which an electronic module including one or more suitable components is disposed or provided, and the display device DD is not limited to one or more embodiments as described.

Referring to FIG. 1D, the display device DD according to one or more embodiments may be folded around a second folding axis FX2 extending in the first direction DR1. The display device DD may be folded around the second folding axis FX2 to be changed into an out-folded state so that the first display surface FS is exposed to the outside. In one or more embodiments, the display device DD may be provided to repeat an operation from a spreading operation to an in-folding or out-folding operation, or vice versa. However, embodiments of the present disclosure are not limited thereto.

FIGS. 1A-1D each illustrates the operation of folding around the one folding axis FX1 or FX2 as an example, but the number of the folding axis and the number of non-folding areas according thereto are not limited thereto. For example, folding around a plurality of folding axes may be performed so that a portion of the first display surface FS and a portion of the second display surface RS face each other. In one or more embodiments, the first and second folding axes FX1 and FX2 are illustrated as being substantially parallel to a long side of the display device DD, but embodiments of the present disclosure are not limited thereto. For example, the first and second folding axes FX1 and FX2 may be substantially parallel to a short side of the display device DD.

In the display device DD, the first non-folding area NFA1 and the second non-folding area NFA2 may each be defined as a portion having the display surfaces FS and RS substantially parallel to a plane defined by the first directional axis DR1 and the second directional axis DR2 in the folded state as illustrated in FIG. 1C. The folding area FA may be defined as an area between the first non-folding area NFA1 and the second non-folding area NFA2. The folding area FA may include a curved portion that is bent to have a set or predetermined curvature in the folded state.

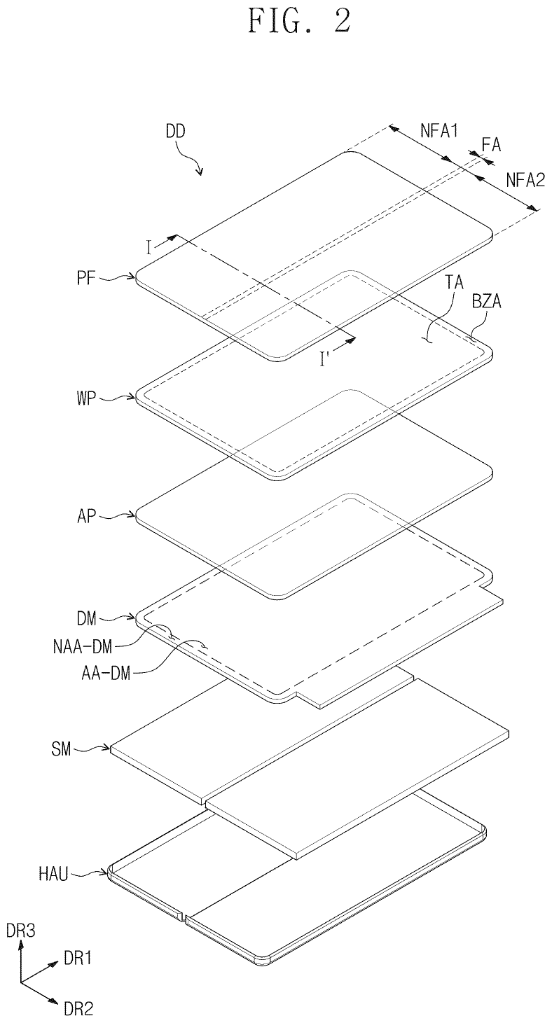

FIG. 2 is an exploded perspective view illustrating a display device DD according to one or more embodiments. Referring to FIG. 2, the display device DD according to one or more embodiments may include a display module DM, a window WP on the display module DM, and an adhesive member AP between the display module DM and the window WP. The display device DD may further include a support member SM below the display module DM, a protective layer PF on the window WP, and a housing HAU that accommodates the display module DM, the support member SM, and/or the like.

The housing HAU may include a material having relatively high rigidity. For example, the housing HAU may include a plurality of frames and/or plates, each of which may be of glass, plastic, and/or metal. The housing HAU may provide a set or predetermined accommodation space. The display module DM may be accommodated in the accommodation space to be protected against an external impact.

The support member SM may include a metal material and/or a polymer material. For example, the support member SM may be of stainless steel, aluminum, and/or an alloy thereof. In one or more embodiments, the support member SM may be of carbon fiber reinforced plastic (CFRP) and/or the like. However, embodiments of the present disclosure are not limited thereto, and the support member SM may include a non-metal material, plastic, glass fiber reinforced plastic, and/or glass. In one or more embodiments, the support member SM may not be provided.

In one or more embodiments, the display device DD may further include a cushion layer, a shielding layer, and/or the like, which may be below the support member SM. The cushion layer may include an elastomer, such as a sponge, a foam, and/or a urethane resin. The shielding layer may be an electromagnetic wave shielding layer and/or a heat dissipation layer.

The display module DM may be activated in response to an electrical signal. The display module DM may be activated to display the image IM (see FIG. 1A) on the display surface FS (see FIG. 1A) of the display device DD. A display area AA-DM and a non-display area NAA-DM may be defined in the display module DM. The display area AA-DM may be an area that is activated in response to an electrical signal. The non-display area NAA-DM may be an area substantially adjacent to at least one side of the display area AA-DM. A circuit, lines, and/or the like to drive the display area AA-DM may be in the non-display area NAA-DM.

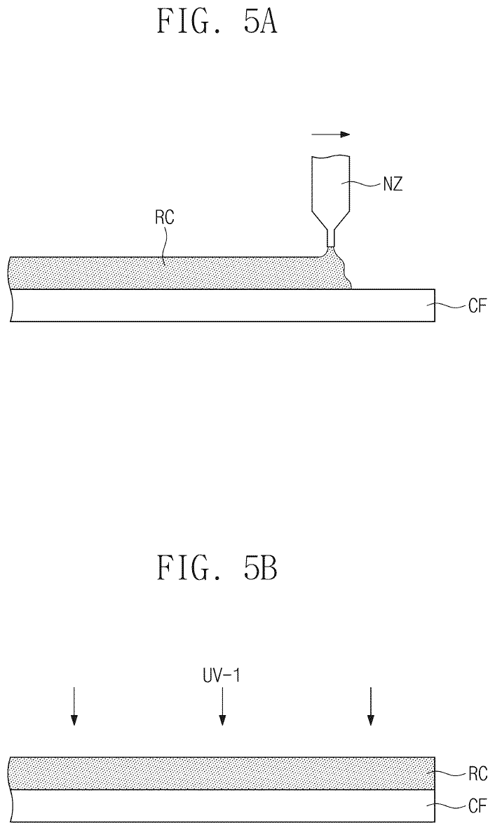

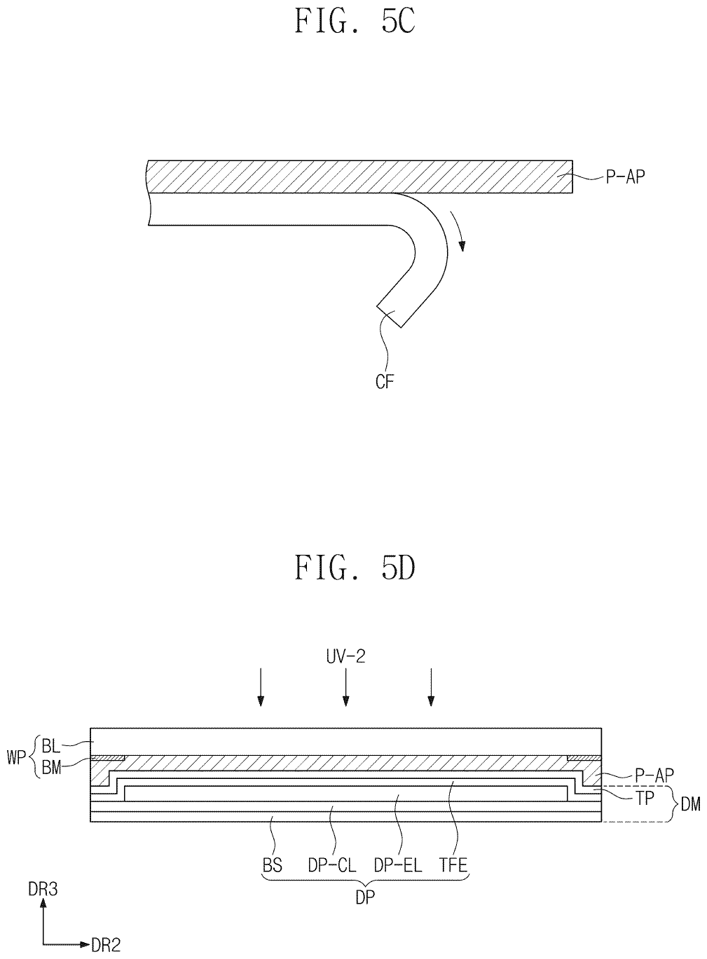

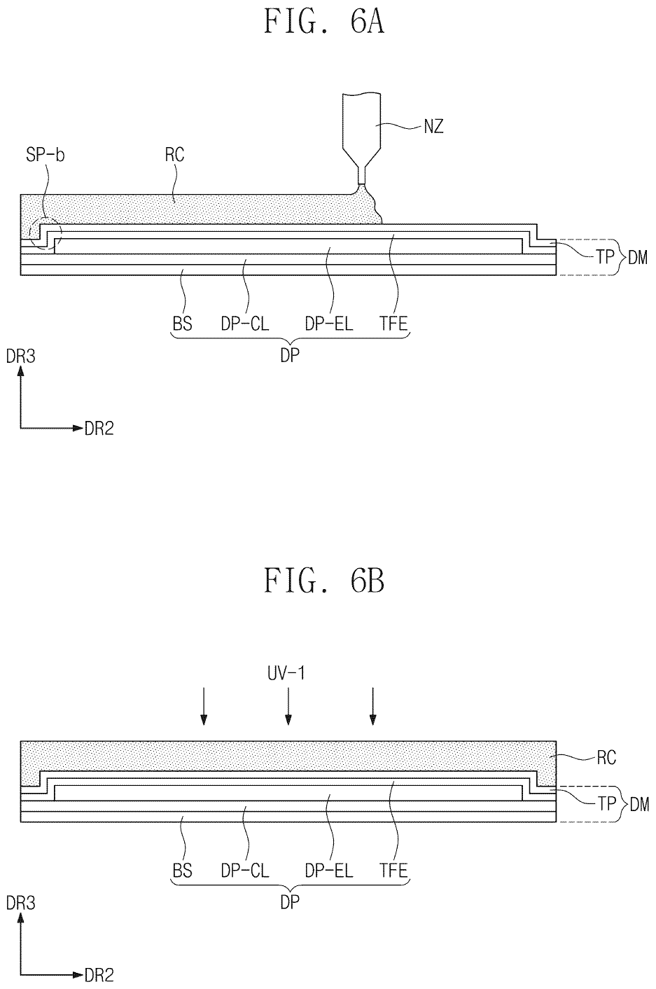

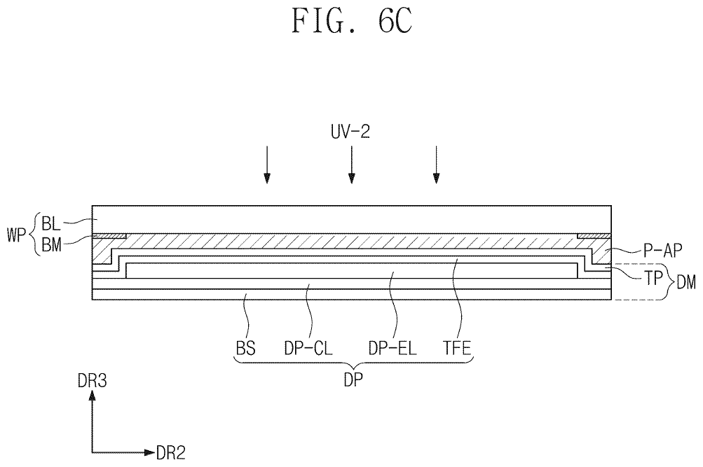

The adhesive member AP may be on the display module DM. The display module DM and the window WP may be coupled to each other through the adhesive member AP. In one or more embodiments, the adhesive member AP may include a polymer derived from a resin composition RC (see FIGS. 5A and 6A) to be further described herein. In one or more embodiments, the adhesive member AP may be made or provided by photocuring the resin composition RC (see FIGS. 5A and 6A). The adhesive member AP made or provided from the resin composition RC (see FIGS. 5A and 6A) according to one or more embodiments may exhibit excellent or suitable impact resistance, excellent or suitable reliability of adhesion, and/or excellent or suitable light fastness. In one or more embodiments, the adhesive member AP made or provided from the resin composition RC (see FIGS. 5A and 6A) according to one or more embodiments may exhibit a characteristic of being easy to repeatedly fold and unfold.

The window WP may include a glass substrate. The window WP may protect the display module DM and/or the like. The image IM (see FIG. 1A) generated or provided in the display module DM may pass through the window WP to be provided for a user. For example, the window WP may include ultra thin glass (UTG).

The window WP may include a transmission area TA and/or a bezel area BZA. The transmission area TA may overlap at least a portion of the display area AA-DM of the display module DM. The transmission area TA may be an optically transparent area. The image IM (see FIG. 1A) may be provided for a user through the transmission area TA.

The bezel area BZA may be an area having a relatively low light transmittance compared to the transmission area TA. The bezel area BZA may define a shape of the transmission area TA. The bezel area BZA may be substantially adjacent to the transmission area TA and surround the transmission area TA.

The bezel area BZA may have a set or predetermined color. The bezel area BZA may cover the non-display area NAA-DM of the display module DM to prevent the non-display area NAA-DM from being visible from the outside. However, embodiments of the present disclosure are not limited to that illustrated herein. For example, the bezel area BZA may be substantially adjacent to only one side of the transmission area TA, or at least a portion thereof may not be provided.

The protective layer PF may be a functional layer that protects one surface (e.g., top surface) of the window WP. The protective layer PF may include polyethylene terephthalate (PET). The protective layer PF may include an anti-fingerprint coating agent, a hard coating agent, an antistatic agent, and/or the like. An auxiliary adhesive layer may be between the window WP and the protective layer PF, and the auxiliary adhesive layer may include a polymer derived from the resin composition RC (see FIGS. 5A and 6A) according to one or more embodiments to be further described herein. In one or more embodiments, the protective layer PF may not be provided.

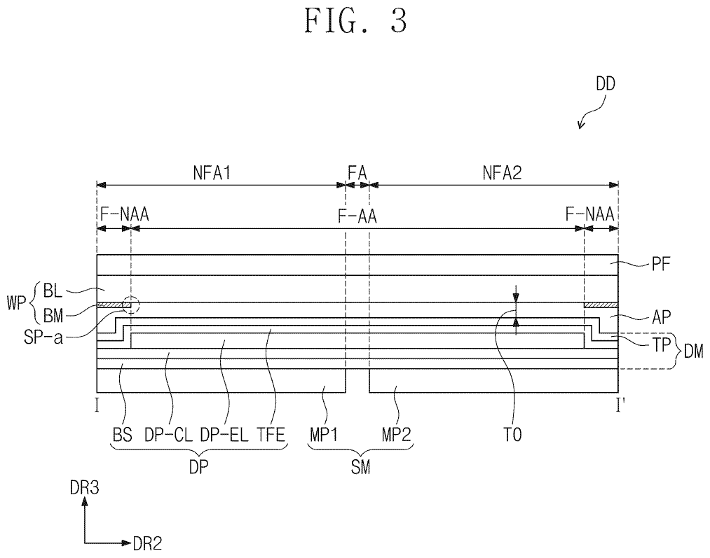

FIG. 3 is a cross-sectional view illustrating a portion corresponding to line I-I′ in FIG. 2. FIG. 3 is a cross-sectional view illustrating a display device DD according to one or more embodiments. FIG. 3 does not provide a housing HAU for ease of description and illustrates a support member SM, a display module DM, an adhesive member AP, a window WP, and a protective layer PF.

Referring to FIG. 3, the support member SM may include a first support portion MP1 overlapping a first non-folding area NFA1 and a second support portion MP2 overlapping a second non-folding area NFA2. Each of the first support portion MP1 and the second support portion MP2 may be spaced and/or apart (e.g., spaced apart or separated) from a folding area FA. The first support portion MP1 and the second support portion MP2 may not overlap the folding area FA. In one or more embodiments, at least a portion of the first support portion MP1 and at least a portion of the second support portion MP2 may overlap the folding area FA.

The display module DM may include a display panel DP and an input sensing part TP on the display panel DP. The display panel DP may include a base substrate BS, a circuit layer DP-CL on the base substrate BS, a display element layer DP-EL on the circuit layer DP-CL, and an encapsulation layer TFE that may cover the display element layer DP-EL. The adhesive member AP may be between the display panel DP and the window WP. The adhesive member AP may be between the input sensing part TP and the window WP.

The components of the display panel DP illustrated in FIG. 3 are illustrative, and the components of the display panel DP are not limited thereto. For example, the display panel DP may include a liquid crystal display element, and in one or more embodiments, the encapsulation layer TFE may not be provided.

The base substrate BS may provide a base surface on which the circuit layer DP-CL may be disposed or provided. The base substrate BS may be a flexible substrate capable of being bent, folded, rolled, and/or the like. The base substrate BS may be a glass substrate, a metal substrate, a polymer substrate, and/or the like. However, embodiments of the present disclosure are not limited thereto, and the base substrate BS may include an inorganic layer, an organic layer, and/or a composite material layer.

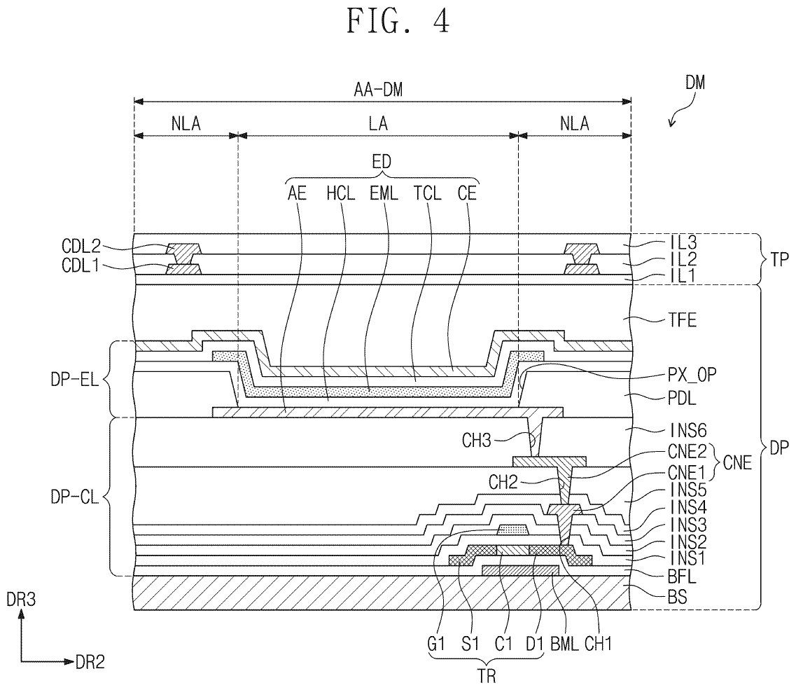

The circuit layer DP-CL may include an insulation layer, a semiconductor pattern, a conductive (e.g., electrically conductive) pattern, a signal line, and/or the like. For example, the circuit layer DP-CL may include a switching transistor and a driving transistor each to drive a light emitting element ED (see FIG. 4) of the display element layer DP-EL.

The display element layer DP-EL may include the light emitting element ED (see FIG. 4) that emits light. For example, the light emitting element ED (see FIG. 4) may include an organic light emitting material, an inorganic light emitting material, an organic-inorganic light emitting material, a quantum dot, a quantum rod, a micro LED, and/or a nano LED.

The encapsulation layer TFE may be on the display element layer DP-EL. The encapsulation layer TFE may protect the display element layer DP-EL from moisture, oxygen, and/or foreign matter, such as dust particles. The encapsulation layer TFE may include at least one inorganic layer. The encapsulation layer TFE may include at least one organic layer and at least one inorganic layer. For example, the encapsulation layer TFE may include an inorganic layer, an organic layer, and/or an inorganic layer which are stacked in sequence.

The input sensing part TP may be between the display panel DP and the window WP. For example, the input sensing part TP may be directly on the encapsulation layer TFE of the display panel DP.

In one or more embodiments, if (e.g., when) one component is referred to as being disposed/provided directly on another component, it refers to that a third component is not disposed/provided between the one component and the other component. For example, if (e.g., when) one component is referred to as being “disposed/provided directly” on another component, it refers to that the one component and the other component are in “contact” with each other.

The input sensing part TP may sense an external input to covert the external input into a set or predetermined input signal and provide the input signal to the display panel DP. For example, in the display device DD according to one or more embodiments, the input sensing part TP may be a touch sensing part that senses a touch. The input sensing part TP may perceive a direct touch by a user, an indirect touch by a user, a direct touch by an object, an indirect touch by an object, and/or the like.

The input sensing part TP may sense at least one selected from among a position of a touch applied from the outside and an intensity (pressure) of the touch. In one or more embodiments, the input sensing part TP may have one or more suitable structures or be of one or more suitable materials, and is not limited to one or more embodiments as described. For example, the input sensing part TP may sense an external input by using a capacitance method. The display panel DP may receive an input signal from the input sensing part TP and generate an image corresponding to the input signal.

The window WP may include a base layer BL and a print layer BM. The window WP may further include at least one functional layer on the base layer BL. For example, the functional layer may be a hard coating layer, an anti-fingerprint coating layer, and/or the like, but embodiments of the present disclosure are not limited thereto.

The base layer BL may be a glass substrate. In one or more embodiments, the base layer BL may be a plastic substrate. For example, the base layer BL may be of polyimide, polyacrylate, polymethylmethacrylate, polycarbonate, polyethylene naphthalate, polyvinylidene chloride, polyvinylidene difluoride, polystyrene, ethylene vinyl alcohol copolymer, or a combination thereof.

The print layer BM may be on one surface of the base layer BL. The print layer BM may be on a bottom surface of the base layer BL, which is substantially adjacent to the display module DM. The print layer BM may be on an edge area of the base layer BL. The print layer BM may be an ink print layer. The print layer BM may be a layer provided by including a pigment and/or a dye. In the window WP, a bezel area BZA may be a portion on which the print layer BM may be provided.

A stepped portion SP-a may be between the print layer BM and a portion of the base layer BL on which the print layer BM is not provided. The adhesive member AP may be made or provided from the resin composition RC (see FIGS. 5A and 6A) according to one or more embodiments and thus may be attached or coupled to the window WP without being separated from the stepped portion SP-a.

The adhesive member AP may have a thickness TO of about 10 μm to about 500 μm, about 30 μm to about 300 μm, or about 50 μm to about 200 μm. For example, the thickness TO of the adhesive member AP may be about 50 μm to about 100 μm. However, this is illustrative, and the thickness TO of the adhesive member AP is not limited thereto.

In one or more embodiments, the adhesive member AP may have a tensile modulus of about 10 MPa to about 900 MPa at a temperature of about 25° C. The tensile modulus may be measured using RSA-G2 (product by TA instruments) that is a dynamic viscoelasticity measurement device. An adhesive member having a tensile modulus of less than about 10 MPa at the temperature of about 25° C. may have low impact resistance, and thus damage thereto may occur if (e.g., when) an impact is applied. An adhesive member having a tensile modulus of more than about 900 MPa at the temperature of about 25° C. may not be easy to repeatedly fold and unfold, and thus may not be suitable as a component of a foldable display device. In one or more embodiments, the adhesive member AP according to one or more embodiments having the tensile modulus of about 10 MPa to about 900 MPa at the temperature of about 25° C. may exhibit excellent or suitable impact resistance and/or may exhibit a characteristic of being easy to repeatedly fold and unfold.

In one or more embodiments, the adhesive member AP may have a 180° peel strength of about 500 gf/25 mm or more for at least one selected from among a glass substrate and a polymer substrate at the temperature of about 25° C. The polymer substrate may include polyethylene terephthalate (PET). For example, the 180° peel strength of the adhesive member AP for at least one selected from among the glass substrate and the polymer substrate at the temperature of about 25° C. may be about 2,000 gf/25 mm or less, about 1,800 gf/25 mm or less, or about 1,600 gf/25 mm or less. An adhesive member, which has a 180° peel strength of less than about 500 gf/25 mm for the glass substrate or the polymer substrate at the temperature of about 25° C., may have low adhesion, and thus may be separated from a component (e.g., window, display module, and/or the like) substantially adjacent thereto if (e.g., when) included in the display device. In one or more embodiments, the adhesive member AP having the 180° peel strength of about 500 gf/25 mm or more for at least one selected from among the glass substrate and the polymer substrate at the temperature of about 25° C. may exhibit excellent or suitable reliability of adhesion.

In one or more embodiments, the adhesive member AP may have a yellow index (YI) of about 1 or less after a light fastness test according to DIN75220 method. A use environment of the display device may include a case in which the display device is exposed to external light, such as ultraviolet light. The light fastness test may be performed to confirm resistance to discoloration, fading, and/or the like if (e.g., when) the adhesive member is exposed to ultraviolet light and/or the like.

An adhesive member having a yellow index (YI) of more than about 1 after the light fastness test according to DIN75220 method may have low resistance to discoloration, fading, and/or the like if (e.g., when) the adhesive member is exposed to ultraviolet light and/or the like, and if (e.g., when) time the adhesive member is exposed to external light, such as ultraviolet light is accumulated, discoloration and/or fading may occur. The adhesive member, in which discoloration and/or fading have occurred, may reduce the display quality if (e.g., when) an image generated from the display module below the adhesive member is provided. The image generated from the display module may pass through the adhesive member to be provided for a user. In one or more embodiments, the adhesive member AP having the yellow index (YI) of about 1 or less after the light fastness test according to DIN 75220 method may have high resistance to discoloration, fading, and/or the like if (e.g., when) being exposed to ultraviolet light and/or the like, and thus may exhibit excellent or suitable light fastness. In one or more embodiments, the display device DD including adhesive member AP according to one or more embodiments may exhibit excellent or suitable display quality.

FIG. 4 is a cross-sectional view illustrating the display module DM in FIG. 3. The components of the display module DM illustrated in FIG. 4 are illustrative, and embodiments of the present disclosure are not limited thereto.

In FIG. 4, a base substrate BS may include a single layer or a plurality of layers. For example, the base substrate BS may include a first synthetic resin layer, an inorganic layer having a multilayer or single-layer structure, and a second synthetic resin layer on the inorganic layer having the multilayer or single-layer structure. Each of the first synthetic resin layer and the second synthetic resin layer may include a polyimide-based resin. Each of the first synthetic resin layer and the second synthetic resin layer may include at least one selected from among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. The term “X-based” resin used herein refers to a resin including a functional group of “X”.

A display panel DP may include a transistor TR and/or a light emitting element ED. The transistor TR and the light emitting element ED may be on the base substrate BS. FIG. 4 illustrates one transistor TR, but the display panel DP may substantially include a plurality of transistors and/or at least one capacitor to drive the light emitting element ED.

A circuit layer DP-CL may be on the base substrate BS. The circuit layer DP-CL may include a shielding electrode BML, a transistor TR, a connection electrode CNE, and a plurality of insulation layers BFL and INS1 to INS6. The plurality of insulation layers BFL and INS1 to INS6 may include a buffer layer BFL and first to sixth insulation layers INS1 to INS6. However, a stack structure of the circuit layer DP-CL illustrated in FIG. 4 is illustrative, and the stack structure of the circuit layer DP-CL may be suitably modified or changed according to the configuration or arrangement of the display panel DP and a process of the circuit layer DP-CL and/or the like.

The shielding electrode BML may be on the base substrate BS. The shielding electrode BML may overlap the transistor TR. The shielding electrode BML may protect the transistor TR by blocking light which is incident (or by reducing an amount of incident light) on the transistor TR from below the display panel DP. The shielding electrode BML may include a conductive (e.g., electrically conductive) material. If (e.g., when) a voltage is applied to the shielding electrode BML, a threshold voltage of the transistor TR on the shielding electrode BML may be maintained. However, embodiments of the present disclosure are not limited thereto, and the shielding electrode BML may be a floating electrode. The shielding electrode BML may not be provided.

The buffer layer BFL may be on the base substrate BS to cover the shielding electrode BML. The buffer layer BFL may include an inorganic layer. The buffer layer BFL may improve or enhance a bonding force between the base substrate BS and a semiconductor pattern or conductive (e.g., electrically conductive) pattern on the buffer layer BFL.

The transistor TR may include a source S1, a channel C1, a drain D1, and/or a gate G1. The source S1, the channel C1, and the drain D1 of the transistor TR may be provided from the semiconductor pattern. The semiconductor pattern of the transistor TR may include polysilicon, amorphous silicon, and/or metal oxide, and the material thereof may be applied without being limited as long as having semiconductor properties, and is not limited thereto.

The semiconductor pattern may include a plurality of regions divided according to a magnitude of conductivity (e.g., electrical conductivity). A region of the semiconductor pattern, which is doped with a dopant or in which a metal oxide is reduced, may have high conductivity (e.g., electrical conductivity), and may substantially act or serve as each of a source electrode and a drain electrode of the transistor TR. The region, which has high conductivity (e.g., electrical conductivity), of the semiconductor pattern may correspond to each of the source S1 and the drain D1 of the transistor TR. A region, which has low conductivity (e.g., electrical conductivity) by being non-doped or doped at a low concentration or by a metal oxide being non-reduced, of the semiconductor pattern may correspond to the channel C1 (or active) of the transistor TR.

The first insulation layer INS1 may cover the semiconductor pattern of the transistor TR and be on the buffer layer BFL. The gate G1 of the transistor TR may be on the first insulation layer INS1. The gate G1 may overlap the channel C1 of the transistor TR on a plane. The gate G1 may function (or act or serve) as a mask in a process of doping the semiconductor pattern of the transistor TR.

The second insulation layer INS2 may cover the gate G1 and be on the first insulation layer INS1. The third insulation layer INS3 may be on the second insulation layer INS2.

The connection electrode CNE may include a first connection electrode CNE1 and a second connection electrode CNE2 which are provided to electrically connect or couple the transistor TR and the light emitting element ED to each other. However, the components of the connection electrode CNE, which electrically connect or couple the transistor TR and the light emitting element ED to each other, may not be limited thereto. For example, one selected from among the first and second connection electrodes CNE1 and CNE2 may not be provided, or an additional connection electrode may be further included.

The first connection electrode CNE1 may be on the third insulation layer INS3. The first connection electrode CNE1 may be connected or coupled to the drain D1 through a first contact hole CH1 passing through the first to third insulation layers INS1 to INS3. The fourth insulation layer INS4 may cover the first connection electrode CNE1 and be on the third insulation layer INS3. The fifth insulation layer INS5 may be on the fourth insulation layer INS4.

The second connection electrode CNE2 may be on the fifth insulation layer INS5. The second connection electrode CNE2 may be connected or coupled to the first connection electrode CNE1 through a second contact hole CH2 passing through the fourth and fifth insulation layers INS4 and INS5. The sixth insulation layer INS6 may cover the second connection electrode CNE2 and be on the fifth insulation layer INS5.

Each of the first to sixth insulation layers INS1 to INS6 may include an inorganic layer and/or an organic layer. For example, the inorganic layer may include at least one selected from among an aluminum oxide, a titanium oxide, a silicon oxide, a silicon oxynitride, a zirconium oxide, and a hafnium oxide. The organic layer may include at least one selected from among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin.

A display element layer DP-EL may include a pixel defining film PDL and the light emitting element ED. The light emitting element ED may include a first electrode AE, a hole control layer HCL, a light emitting layer EML, an electron control layer TCL, and a second electrode CE.

The first electrode AE may be on the sixth insulation layer INS6. The first electrode AE may be connected or coupled to the second connection electrode CNE2 through a third contact hole CH3 passing through the sixth insulation layer INS6. The first electrode AE may be electrically connected or coupled to the drain D1 of the transistor TR through the first and second connection electrodes CNE1 and CNE2.

The first electrode AE may be of a metal material, a metal alloy, and/or a conductive (e.g., electrically conductive) compound. The first electrode AE may be an anode or a cathode. However, embodiments of the present disclosure are not limited thereto. The first electrode AE may be a pixel electrode. The first electrode AE may be a transmissive electrode, a semi-transmissive electrode, or a reflective electrode. The first electrode AE may include at least one selected from silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode AE is a transmissive electrode, the first electrode AE may include a transparent metal oxide, for example, an indium tin oxide (ITO), an indium zinc oxide (IZO), a zinc oxide (e.g., ZnO), an indium tin zinc oxide (ITZO), and/or the like. If (e.g., when) the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (e.g., mixture of Ag and Mg). In one or more embodiments, the first electrode AE may have a multilayer structure including a reflective film or a semi-transmissive film, each of which may be of the foregoing material, and a transparent conductive (e.g., electrically conductive) film of an indium tin oxide (ITO), an indium zinc oxide (IZO), a zinc oxide (e.g., ZnO), an indium tin zinc oxide (ITZO), and/or the like. For example, the first electrode AE may have a three-layer structure of ITO/Ag/ITO, but is not limited thereto. However, embodiments of the present disclosure are not limited thereto, and the first electrode AE may include the foregoing metal material, a combination of two or more metal materials selected from the foregoing metal materials, an oxide of the foregoing metal materials, and/or the like.

The pixel defining film PDL may be on the sixth insulation layer INS6. A light emitting opening portion PX_OP which exposes a portion of the first electrode AE may be defined in the pixel defining film PDL. The portion of the first electrode AE, which is exposed by the light emitting opening portion PX_OP, may be defined as a light emitting area LA.

A display area AA-DM of the display module DM may include the light emitting area LA and/or a light shielding area NLA. An area in which the pixel defining film PDL is disposed or provided may correspond to the light shielding area NLA. The light shielding area NLA may surround the light emitting area LA within the display area AA-DM.

The hole control layer HCL may be on the first electrode AE and the pixel defining film PDL. The hole control layer HCL may act or serve as a common layer overlapping the light emitting area LA and the light shielding area NLA. In one or more embodiments, the hole control layer HCL may be provided only in an area corresponding to the light emitting opening portion PX_OP. The hole control layer HCL may include at least one selected from among a hole transport layer, a hole injection layer, and an electron blocking layer. The hole control layer HCL may include a generally available hole injection material and/or a generally available hole transport material.

The light emitting layer EML may be on the hole control layer HCL. The light emitting layer EML may be in an area corresponding to the light emitting opening portion PX_OP. In one or more embodiments, the light emitting layer EML may act or serve as a common layer. The light emitting layer EML may include an organic light emitting material and/or an inorganic light emitting material. The light emitting layer EML may emit light having any one color selected from among red, green, and blue colors. For example, the light emitting layer EML may emit light having a blue color.

The electron control layer TCL may be on the light emitting layer EML. The electron control layer TCL may act or serve as a common layer overlapping the light emitting area LA and the light shielding area NLA. In one or more embodiments, the electron control layer TCL may be provided only in an area corresponding to the light emitting opening portion PX_OP. The electron control layer TCL may include at least one selected from among an electron transport layer, an electron injection layer, and a hole blocking layer. The electron control layer TCL may include a generally available electron injection material and/or a generally available electron transport material.

The second electrode CE may be on the electron control layer TCL. The second electrode CE may act or serve as a common layer overlapping the light emitting area LA and the light shielding area NLA.

The second electrode CE may be a common electrode. The second electrode CE may be a cathode or an anode, but embodiments of the present disclosure are not limited thereto. For example, if (e.g., when) the first electrode AE is an anode, the second electrode CE may be a cathode, and if (e.g., when) the first electrode AE is a cathode, the second electrode CE may be an anode.

The second electrode CE may be a transmissive electrode, a semi-transmissive electrode, or a reflective electrode. If (e.g., when) the second electrode CE is a transmissive electrode, the second electrode CE may be of a transparent metal oxide, for example, an indium tin oxide (ITO), an indium zinc oxide (IZO), a zinc oxide (e.g., ZnO), an indium tin zinc oxide (ITZO), and/or the like.

If (e.g., when) the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgYb). In one or more embodiments, the second electrode CE may have a multilayer structure including a reflective film or a semi-transmissive film, each of which may be of the foregoing material, and a transparent conductive (e.g., electrically conductive) film of an indium tin oxide (ITO), an indium zinc oxide (IZO), a zinc oxide (e.g., ZnO), an indium tin zinc oxide (ITZO), and/or the like. For example, the second electrode CE may include the foregoing metal material, a combination of two or more metal materials selected from the foregoing metal materials, an oxide of the foregoing metal materials, and/or the like.

An encapsulation layer TFE may be on the second electrode CE to cover the light emitting element ED. The encapsulation layer TFE may include a plurality of thin films. For example, the encapsulation layer TFE may include inorganic films on the second electrode CE and an organic film between the inorganic films. The inorganic films may protect the light emitting element ED from moisture and/or oxygen, and the organic film may protect the light emitting element ED from foreign matter, such as dust particles.

An input sensing part TP may include a first sensing insulation layer IL1, a second sensing insulation layer IL2, and a third sensing insulation layer IL3. The input sensing part TP may include at least one conductive (e.g., electrically conductive) layer on the sensing insulation layers. The input sensing part TP may include a first conductive layer CDL1 and a second conductive layer CDL2.

The first sensing insulation layer IL1 may be on the encapsulation layer TFE. The first sensing insulation layer IL1 may include at least one inorganic insulation layer. The first sensing insulation layer IL1 may be in contact with the encapsulation layer TFE. In one or more embodiments, the first sensing insulation layer IL1 may not be provided, and in one or more embodiments, the first conductive layer CDL1 may be in contact with the encapsulation layer TFE.

The first conductive layer CDL1 may be on the first sensing insulation layer IL1. The first conductive layer CDL1 may include a plurality of first conductive (e.g., electrically conductive) patterns. The plurality of first conductive (e.g., electrically conductive) patterns may be on the first sensing insulation layer IL1. The second sensing insulation layer IL2 may be on the first sensing insulation layer IL1 to cover at least a portion of the first conductive layer CDL1.

The second conductive layer CDL2 may be on the second sensing insulation layer IL2. The second conductive layer CDL2 may include a plurality of second conductive (e.g., electrically conductive) patterns. The plurality of second conductive (e.g., electrically conductive) patterns may be on the second sensing insulation layer IL2. The plurality of second conductive (e.g., electrically conductive) patterns may be connected or coupled to the plurality of first conductive (e.g., electrically conductive) patterns through contact holes defined in the second sensing insulation layer IL2, respectively.

Each of the plurality of first conductive (e.g., electrically conductive) patterns of the first conductive layer CDL1 and the plurality of second conductive (e.g., electrically conductive) patterns of the second conductive layer CDL2 may correspond to the light shielding area NLA. Each of the plurality of first conductive (e.g., electrically conductive) patterns of the first conductive layer CDL1 and the plurality of second conductive (e.g., electrically conductive) patterns of the second conductive layer CDL2 may correspond to a mesh pattern.

The third sensing insulation layer IL3 may be on the second sensing insulation layer IL2 and may cover the second conductive layer CDL2. Each of the second sensing insulation layer IL2 and the third sensing insulation layer IL3 may include an inorganic insulation layer and/or an organic insulation layer.

Each of the first conductive layer CDL1 and the second conductive layer CDL2 may have a single-layer structure or may have a multilayer structure in which layers are stacked in the third direction DR3. The conductive layers CDL1 and CDL2 each having a single-layer structure may include a metal layer and/or a transparent conductive (e.g., electrically conductive) layer. The metal layer may include molybdenum, silver, titanium, copper, aluminum, and/or an alloy thereof. The transparent conductive (e.g., electrically conductive) layer may include a transparent conductive (e.g., electrically conductive) oxide, such as an indium tin oxide (ITO), an indium zinc oxide (IZO), a zinc oxide (e.g., ZnO), an indium zinc tin oxide (IZTO), and/or the like. The transparent conductive (e.g., electrically conductive) layer may include a conductive (e.g., electrically conductive) polymer, such as poly(3,4-ethylenedioxythiophene) (PEDOT), a metal nanowire, graphene, and/or the like.

The conductive layers CDL1 and CDL2 each having a multilayer structure may include metal layers. The metal layers may have, for example, a three-layer structure of titanium (Ti)/aluminum (Al)/titanium (Ti). Each of the conductive layers CDL1 and CDL2 having a multilayer structure may include at least one metal layer and at least one transparent conductive (e.g., electrically conductive) layer.

FIGS. 5A-5D each is a schematic view illustrating a method for manufacturing the adhesive member AP (see FIG. 3) from a resin composition RC according to one or more embodiments. For example, the method for manufacturing the adhesive member AP (see FIG. 3) may include providing the resin composition RC on a substrate CF, providing first light UV-1 to the resin composition RC to form or provide a preliminary adhesive member P-AP, and providing second light UV-2 to the preliminary adhesive member P-AP to form or provide the adhesive member AP (see FIG. 3). Hereinafter, one or more embodiments will be described with reference to FIGS. 5A-5D without describing the contents in common with the contents described with reference to FIGS. 1-4, and mainly or predominantly in terms of differences.

Referring to FIG. 5A, the resin composition RC according to one or more embodiments may be provided on the substrate CF. The resin composition RC may be provided on the substrate CF through a nozzle NZ. For example, the substrate CF on which the resin composition RC is provided may include polyethylene terephthalate (PET). The substrate CF may be a temporary substrate used to form or provide the adhesive member AP (see FIG. 3) from the resin composition RC, and a substrate may be used without being limited as long as the resin composition RC is easily detachable therefrom after being cured. One surface of the substrate CF on which the resin composition RC is provided may have been release-treated.

The resin composition RC according to one or more embodiments may be provided by an inkjet printing method or a dispensing method. If (e.g., when) the resin composition RC is provided by the inkjet printing method or the dispensing method, the resin composition RC may exhibit a characteristic of being easy to apply or provide onto members having one or more suitable shapes included in the display device DD (see FIG. 1A).

The resin composition RC in a liquid state may be provided in a uniform (e.g., substantially uniform) amount and/or at a uniform (e.g., substantially uniform) rate. FIG. 5A illustrates the resin composition RC being provided through the nozzle NZ, but a machine for providing the resin composition RC is not limited thereto.

The resin composition RC according to one or more embodiments may have a shear viscosity of about 8 mPa·s to about 50 mPa·s as measured at a temperature of about 25° C. according to JIS Z8803 method. The resin composition RC having the shear viscosity of about 8 mPa·s to about 50 mPa·s as measured at the temperature of about 25° C. according to JIS Z8803 method may exhibit a low-viscosity characteristic and thus may be provided by an inkjet printing method or a dispensing method. In a resin composition having a shear viscosity of less than about 8 mPa's as measured at the temperature of about 25° C. according to JIS Z8803 method, flowing may occur if (e.g., when) the resin composition is provided. The “flowing” refers to a phenomenon in which the resin composition flows out of a member to which the resin composition is intended to be provided. A resin composition having a shear viscosity of more than about 50 mPa·s as measured at the temperature of about 25° C. according to JIS Z8803 method may not be easily ejected from a machine, such as the nozzle NZ, and may not be applied in a uniform (e.g., substantially uniform) amount and/or in a uniform (e.g., substantially uniform) thickness.

The resin composition RC according to one or more embodiments may include a polybutadiene having an unsaturated bond (e.g., a double bond between carbon atoms) in at least one selected from among a main chain and a side chain, at least one photoinitiator, at least one monofunctional (meth)acrylate monomer, and/or at least one (meth)acrylate oligomer. In one or more embodiments, a (meth)acryloyl group refers to an acryloyl group or a methacryloyl group, and a (meth)acryl group refers to an acryl group or a methacryl group.

The resin composition RC according to one or more embodiments may not include a urethane (meth)acrylate-terminated polybutadiene. The urethane (meth)acrylate-terminated polybutadiene may include a urethane (meth)acrylate-terminated 1,2-polybutadiene (e.g., TE-2000 or TEA-1000 that is a product by Nippon Soda Co., Ltd.), a urethane acrylate-terminated polybutadiene (e.g., TEAI-1000 that is a product by Nippon Soda Co., Ltd.), a urethane (meth)acrylate-terminated 1,4-polybutadiene (e.g., BAC-45 that is a product by Osaka Organic Chemical Industry Ltd.), and/or the like, and the resin composition according to one or more embodiments does not include the foregoing materials.

The resin composition RC according to one or more embodiments may not include a prodegradent. The prodegradent may be included in a material to peel off an adhesive member, and an adhesive member made or provided from a resin composition including the prodegradent may have low adhesion. Thus, this adhesive member may peel off from an adherend (e.g., display module, window, and/or the like), and may not be suitable as a component of the display device.

The resin composition RC according to one or more embodiments may not include a filler (e.g., organic particles and inorganic particles). The filler may not be dissolved in the resin composition. A resin composition including the filler may not be easily ejected from a machine, such as the nozzle NZ, due to the filler, and may not be suitable to be provided by an inkjet printing method or a dispensing method.

In one or more embodiments, the resin composition RC may include a polybutadiene having an unsaturated bond (e.g., a double bond between carbon atoms) in at least one selected from among a main chain and a side chain. In the resin composition RC, the polybutadiene may include a moiety represented by Formula 1 below. The moiety represented by Formula 1 may have unsaturated bonds (e.g., a double bond between carbon atoms) in a main chain and a side chain. At least one of carbon atom of the moiety represented by Formula 1 may be a bonding site bonded to other moiety (or polymer chain). For example, two carbon atoms at both (e.g., simultaneously) ends of the moiety represented by Formula 1 may be a bonding site.

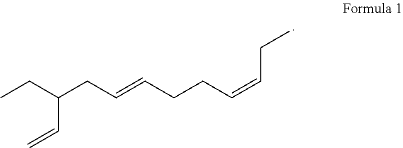

The resin composition RC according to one or more embodiments including the polybutadiene having the unsaturated bond (e.g., the double bond between carbon atoms) in at least one selected from among the main chain and the side chain may exhibit adhesiveness after curing. In one or more embodiments, as the polybutadiene having the unsaturated bond (e.g., the double bond between carbon atoms) in at least one selected from among the main chain and the side chain may trap oxygen radicals, yellowing of the resin composition RC after curing may be prevented or reduced.

Based on a total of 100 wt % (weight percent) of the resin composition RC, an amount of the polybutadiene may be about 1 wt % or more and less than about 10 wt %. The resin composition RC, which includes the polybutadiene according to one or more embodiments satisfying (e.g., being within) the weight range (e.g., about 1 wt % or more and less than about 10 wt %) and also having the unsaturated bond (e.g., the double bond between carbon atoms) in the main chain and/or the side chain, may have a tensile modulus of about 10 MPa to about 900 MPa at a temperature of about 25° C. after photocuring. The resin composition RC, which includes the polybutadiene according to one or more embodiments satisfying (e.g., being within) the weight range and also having the unsaturated bond (e.g., the double bond between carbon atoms) in the main chain and/or the side chain, may have a 180° peel strength of about 500 gf/25 mm or more for at least one selected from among a glass substrate and a polymer substrate at the temperature of about 25° C. after the photocuring. The resin composition RC, which includes the polybutadiene according to one or more embodiments satisfying (e.g., being within) the weight range and also having the unsaturated bond (e.g., the double bond between carbon atoms) in the main chain and/or the side chain, may have a yellow index (YI) of about 1 or less after a light fastness test according to DIN75220 method after the photocuring. In one or more embodiments, the resin composition RC including the polybutadiene according to one or more embodiments may exhibit excellent or suitable reliability after curing.

A resin composition including less than about 1 wt % or more than about 10 wt % of the polybutadiene based on a total of 100 wt % of the resin composition may exhibit a relatively high tensile modulus (e.g., tensile modulus of more than about 900 MPa) and/or a relatively low 180° peel strength (e.g., 180° peel strength of less than about 500 gf/25 mm) after the photocuring. The resin composition including less than about 1 wt % or more than about 10 wt % of the polybutadiene based on a total of 100 wt % of the resin composition may exhibit a yellow index (YI) of more than about 1 after the light fastness test according to DIN75220 method after the photocuring. Thus, the resin composition including less than about 1 wt % or more than about 10 wt % of the polybutadiene based on a total of 100 wt % of the resin composition may not be suitable to form or provide the adhesive member.

The resin composition RC according to one or more embodiments may include at least one photoinitiator. The photoinitiator may include a radical polymerization initiator. For example, the resin composition RC may include Omnirad 819 (product by IGM Resin) as the photoinitiator.

If (e.g., when) the resin composition RC includes a plurality of photoinitiators, different photoinitiators may be activated by ultraviolet light having different center wavelengths. For example, the photoinitiator may include at least one selected from among 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In one or more embodiments, the photoinitiator may include at least one selected from among 2-methyl-1 [4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, etju; (2,4,6-trimethylbenzoyl)phenyl phosphinate, Phenylbis(2,4,6-trimethylbenzoyl) phosphine oxide, [1-(4-phenylsulfanylbenzoyl) heptylideneamino]benzoate, [1-[9-ethyl-6-(2-methylbenzoyl) carbazol-3-yl]ethylideneamino]acetate, and bis(2,4-cyclopentadienyl)bis[2,6-difluoro-3-(1-pyrryl)phenyl]titanium (IV).

In one or more embodiments, the resin composition RC may include at least one monofunctional (meth)acrylate monomer. For example, in the resin composition RC, the monofunctional (meth)acrylate monomer may include at least one selected from among alicyclic (meth)acrylate, hydroxyl group-containing (meth)acrylate, and alkyl (meth)acrylate. The monofunctional (meth)acrylate monomer may include at least one selected from among 4-hydroxybutyl acrylate (4-HBA), isobornyl acrylate (IBXA), and isodecyl acrylate (IDAA).

An amount of the monofunctional (meth)acrylate monomer may be about 82 wt % or more and less than about 92 wt % based on a total of 100 wt % of the resin composition RC. The resin composition RC, which includes the monofunctional (meth)acrylate monomer satisfying (e.g., being within) the weight range as above, may satisfy the foregoing shear viscosity before the curing and may satisfy the foregoing tensile modulus, 180° peel strength, and yellow index after the curing.

The resin composition RC according to one or more embodiments may include at least one (meth)acrylate oligomer. For example, the (meth)acrylate oligomer may include a urethane acrylate oligomer. The (meth)acrylate oligomer may include UV-3700B (product by Mitsubishi Chemical Holdings).

Referring to FIG. 5B, the first light UV-1 may be provided to the resin composition RC applied in a constant thickness on the substrate CF. The liquid resin composition RC may be cured by the first light UV-1 to form or provide the preliminary adhesive member P-AP (see FIG. 5C). The first light UV-1 may be ultraviolet light. FIG. 5B illustrates the preliminary adhesive member P-AP (see FIG. 5C) being formed or provided by emitting the first light UV-1 directly onto the resin composition RC applied on the substrate CF, but embodiments of the present disclosure are not limited thereto. A carrier film may be on the resin composition RC applied in a uniform (e.g., substantially uniform) thickness onto the substrate CF, and the carrier film may transmit ultraviolet light.

Referring to FIGS. 5C and 5D, the preliminary adhesive member P-AP formed or provided by emitting the first light UV-1 (see FIG. 5B) onto the resin composition RC may be detached or decoupled from the substrate CF, and may be provided on one surface of a window WP or one surface of a display module DM. One surface of the preliminary adhesive member P-AP may be laminated on the one surface of the window WP or the one surface of the display module DM, and the one surface of the window WP or the one surface of the display module DM, which may not be attached or coupled, may be attached or coupled to the other surface of the preliminary adhesive member P-AP. Thereafter, the second light UV-2 may be emitted onto the preliminary adhesive member P-AP to form or provide the adhesive member AP (see FIG. 3). The second light UV-2 may be ultraviolet light. The second light UV-2 may be provided from above the window WP, and the window WP may transmit the second light UV-2. The second light UV-2 may pass through the window WP to be provided to the preliminary adhesive member P-AP.

FIGS. 5A-5D each illustrates curing the resin composition RC two times (e.g., performing the curing by providing light two times) to form or provide the adhesive member AP (see FIG. 3), but embodiments of the present disclosure are not limited thereto. For example, the resin composition RC (see FIG. 5A) may be cured once to form or provide the adhesive member AP (see FIG. 3), or in one or more embodiments, may be cured three or more times to form or provide the adhesive member AP (see FIG. 3).

The resin composition RC (see FIG. 5A) according to one or more embodiments may have the tensile modulus of about 10 MPa to about 900 MPa at the temperature of about 25° C. after being cured by the light. The resin composition RC (see FIG. 5A) may have the 180° peel strength of about 500 gf/25 mm or more for at least one selected from among the polymer substrate and the glass substrate at the temperature of about 25° C. after being cured by the light. The resin composition RC (see FIG. 5A) may have the yellow index (YI) of about 1 or less after the light fastness test according to DIN75220 method after being cured by the light. The resin composition RC according to one or more embodiments may include the polybutadiene having the unsaturated bond (e.g., the double bond between carbon atoms) in at least one selected from among the main chain and the side chain, the photoinitiator, the monofunctional (meth)acrylate monomer, and/or the (meth)acrylate oligomer. The amount of the polybutadiene may be about 1 wt % or more and less than about 10 wt % based on a total of 100 wt % of the resin composition RC. In one or more embodiments, the resin composition RC according to one or more embodiments may satisfy the foregoing shear viscosity before the curing and/or may satisfy the foregoing tensile modulus, 180° peel strength, and/or yellow index after the curing.

FIGS. 6A-6C each is a schematic view illustrating a method for manufacturing the adhesive member AP (see FIG. 3) from a resin composition RC according to one or more embodiments. Hereinafter, one or more embodiments will be described with reference to FIGS. 6A-6C without describing the contents in common with the contents described with reference to FIGS. 1-5D, and mainly or predominantly in terms of differences.

The method for manufacturing the adhesive member AP illustrated in FIGS. 6A-6C may include providing the resin composition RC on a display module DM, providing first light UV-1 to the resin composition RC to form or provide a preliminary adhesive member P-AP, and/or providing second light UV-2 to the preliminary adhesive member P-AP to form or provide the adhesive member AP (see FIG. 3). Compare to the manufacturing method illustrated in FIGS. 5A-5D, the manufacturing method illustrated in FIGS. 6A-6C may be different in that the resin composition RC is provided on the display module DM.

The resin composition RC may be provided directly on one surface of the display module DM or one surface of a window WP. FIG. 6A illustrates the resin composition RC being provided directly on the one surface of the display module DM.

The resin composition RC having a shear viscosity of about 8 mPa·s to about 50 mPa·s as measured at a temperature of about 25° C. according to JIS Z8803 method may be provided while covering a bend of a stepped portion SP-b of the display module DM. As the resin composition RC has the low shear viscosity of about 50 mPa·s or less, the resin composition RC may be applied or provided so that an empty space does not occur at a portion with a bend like the stepped portion SP-b. In one or more embodiments, the resin composition RC having the shear viscosity of about 8.0 mPa·s or more may be uniformly (e.g., substantially uniformly) applied in a set or predetermined thickness without flowing out of a portion, e.g., the display module DM, to which the resin composition RC is intended to be provided.

Referring to FIG. 6B, the first light UV-1 may be provided to the uniformly (e.g., substantially uniformly) applied resin composition RC. As the first light UV-1 is provided to the resin composition RC, the preliminary adhesive member P-AP (see FIG. 6C) may be formed or provided. Referring to FIG. 6C, the window WP may be provided on the preliminary adhesive member P-AP. The second light UV-2 may pass through the window WP to be provided to the preliminary adhesive member P-AP. The preliminary adhesive member P-AP may be cured by the second light UV-2 to form or provide the adhesive member AP (see FIG. 3).

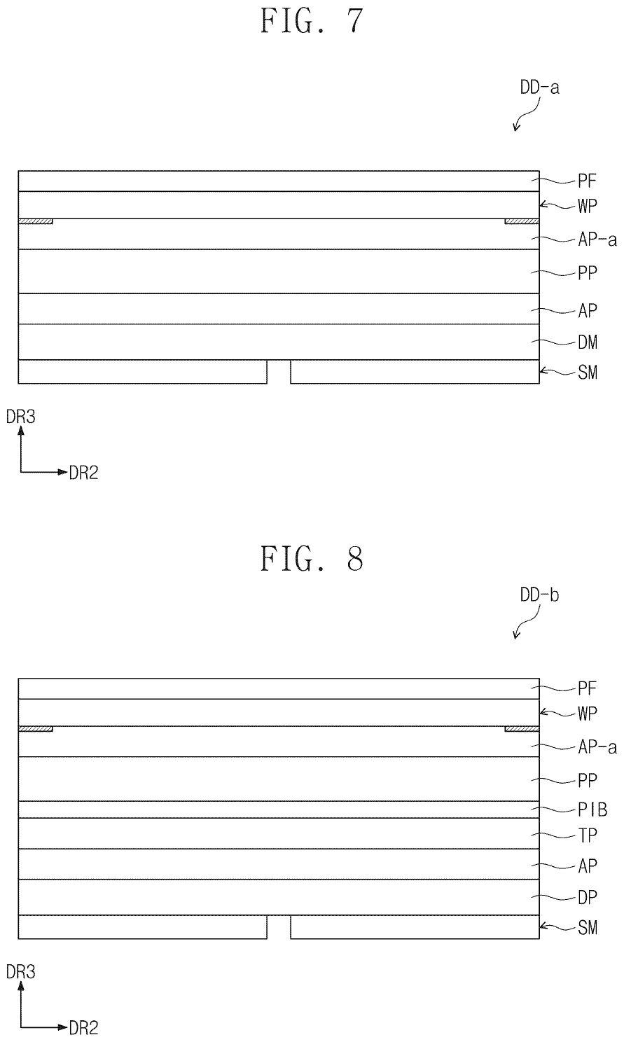

FIG. 7 is a cross-sectional view illustrating a display device DD-a according to one or more embodiments of the present disclosure. Hereinafter, the display device illustrated in FIG. 7 will be described without describing the contents in common with the contents described with reference to FIGS. 1-6C, and mainly or predominantly in terms of differences.

Compared to the display device DD described with reference to FIGS. 2-3, the display device DD-a illustrated in FIG. 7 may further include a light control layer PP and/or an optical adhesive layer AP-a. The display device DD-a according to one or more embodiments may further include the light control layer PP between an adhesive member AP and a window WP and the optical adhesive layer AP-a between the light control layer PP and the window WP. The light control layer PP may include a polarizer or a color filter layer.

The optical adhesive layer AP-a may include a polymer derived from the resin composition RC (see FIGS. 5A and 6A) according to one or more embodiments. The optical adhesive layer AP-a may be made or provided from the resin composition RC (see FIGS. 5A and 6A) according to one or more embodiments. The optical adhesive layer AP-a made or provided from the resin composition RC (see FIGS. 5A and 6A) according to one or more embodiments may have a tensile modulus of about 10 MPa to about 900 MPa at the temperature of about 25° C. The optical adhesive layer AP-a may have a 180° peel strength of about 500 gf/25 mm or more for at least one selected from among a glass substrate and a polymer substrate at a temperature of about 25° C. The optical adhesive layer AP-a may have a yellow index (YI) of about 1 or less after a light fastness test according to DIN75220 method. The optical adhesive layer AP-a including the polymer derived from the resin composition RC (see FIGS. 5A and 6A) according to one or more embodiments may exhibit excellent or suitable impact resistance, excellent or suitable reliability of adhesion, and/or excellent or suitable light fastness.

FIG. 8 is a cross-sectional view illustrating a display device DD-b according to one or more embodiments of the present disclosure. Hereinafter, the display device DD-b according to one or more embodiments illustrated in FIG. 8 will be described without describing the contents in common with the contents described with reference to FIGS. 1-7, and mainly or predominantly in terms of differences.

Compared to the display device DD described with reference to FIGS. 2-3, the display device DD-b illustrated in FIG. 8 may further include a light control layer PP, an optical adhesive layer AP-a, and/or an adhesive interlayer PIB. Like the display device DD-a according to one or more embodiments illustrated in FIG. 7, the display device DD-b according to one or more embodiments illustrated in FIG. 8 may further include the light control layer PP between an adhesive member AP and a window WP and the optical adhesive layer AP-a between the light control layer PP and the window WP.

In the display device DD-b according to one or more embodiments, the adhesive member AP may be provided between a display panel DP and an input sensing part TP. For example, the input sensing part TP may not be directly on the display panel DP, and the display panel DP and the input sensing part TP may be coupled to each other through the adhesive member AP. For example, the adhesive member AP may be between the encapsulation layer TFE (see FIG. 3) of the display panel DP and the input sensing part TP.

The adhesive interlayer PIB may be below the light control layer PP. The adhesive interlayer PIB may be between the input sensing part TP and the light control layer PP, and may be of an adhesive material having excellent or suitable resistance to moisture permeation. For example, the adhesive interlayer PIB may include polyisobutylene. The adhesive interlayer PIB may be on the input sensing part TP to prevent or reduce corrosion of sensing electrodes of the input sensing part TP. The display device DD-b according to one or more embodiments may include the optical adhesive layer AP-a and the adhesive member AP, each of which is made or provided from the resin composition RC (see FIGS. 5A and 6A) according to one or more embodiments, and the display device DD-b including the optical adhesive layer AP-a and the adhesive member AP may exhibit excellent or suitable reliability.

Hereinafter, a resin composition according to one or more embodiments of the present disclosure and an adhesive member made or provided from the resin composition will be specifically described referring to Examples and Comparative Examples. Examples described below are each one example for enhancing understanding, and embodiments of the present disclosure are not limited thereto.

### EXAMPLES

### 1. Preparation and Evaluation of Resin Compositions

Resin compositions according to Examples and Comparative Examples were prepared by using materials set forth in Table 1. The materials set forth in Table 1 were weighted using a light-shielding glass vial in respective amounts (g, gram) and were stirred at room temperature to prepare the resin compositions.

### Shear Viscosity Measurement for Resin Compositions

In Table 1, shear viscosities of the resin compositions were measured at a temperature of about 25° C. according to JIS Z8803 method. The shear viscosities of the resin compositions were measured using viscometer TVE-25L (product by TOKI SANGYO Co. Ltd.) under a rate condition of about 10 rpm.

TABLE 1

| | | Example | Example | Example | Compar. | Compar. | Compar. | Compar. | Compar. | Compar. |
|---|---|---|---|---|---|---|---|---|---|---|
| | | 1 | 2 | 3 | Example 4 | Example 5 | Example 6 | Example 7 | Example 8 | Example 9 |
| Polybutadiene | A-1 | 5 | | 3 | | | | 14 | | |
| | A-2 | | 5 | | | | | | | |
| | A-3 | | | | | | 5 | | | |
| | A-4 | | | | | | | | 5 | |
| | A-5 | | | | | | | | | 5 |
| Photo- | Omnirad | 2 | 2 | 2 | 2 | 2 | 2 | 2 | 2 | 2 |
| initiator | 819 | | | | | | | | | |
| Mono- | 4-HBA | 10 | 10 | 22 | 11 | 23 | 10 | 10 | 10 | 10 |
| functional | IBXA | 57 | 57 | 69 | 60 | 71 | 57 | 55 | 57 | 57 |
| (meth) | IDAA | 22 | 22 | | 23 | | 22 | 22 | 22 | 22 |
| acrylate | | | | | | | | | | |
| monomer | | | | | | | | | | |
| (Meth) | UV- | 4 | 4 | 4 | 4 | 4 | 4 | 4 | 4 | 4 |
| acrylate | 3700B | | | | | | | | | |
| oligomer | | | | | | | | | | |

| | | | | | | | | | |
|---|---|---|---|---|---|---|---|---|---|
| Shear viscosity | 18 | 21 | 24 | 14 | 21 | 19 | 15 | 25 | 20 |
| (25° C., mPa · s] | | | | | | | | | |

### Data of Materials in Table 1

A-1: Polyvest 110 (unsaturated bond-containing polybutadiene, product by Evonik Industries)
A-2: Polyvest EPMAT (methacrylic acid-terminated polybutadiene, product by Evonik Industries)
A-3: GI-3000 (hydrogenated polybutadiene, product by Nippon Soda Co., Ltd.)
A-4: TEAI-1000 (urethane acrylate-terminated hydrogenated polybutadiene, product by Nippon Soda Co., Ltd.)
A-5: TE-2000 (urethane acrylate-terminated polybutadiene, product by Nippon Soda Co., Ltd.)
Omnirad 819: Phenylbis(2,4,6-trimethylbenzoyl) phosphine oxide (product by IGM Resins)
4-HBA: 4-Hydroxybutyl acrylate (product by Osaka Organic Chemical Industry Ltd.)
IBXA: Isobornyl acrylate (product by Osaka Organic Chemical Industry Ltd.)
IDAA: Isodecyl acrylate (product by Osaka Organic Chemical Industry Ltd.)
UV-3700B: Urethane acrylate (product by Mitsubishi Chemical Holdings)

In Table 1, each of A-1 and A-2 as a polybutadiene has an unsaturated bond (e.g., a double bond between carbon atoms) in at least one selected from among a main chain and a side chain and is a polybutadiene according to one or more embodiments. A-3 as a polybutadiene, which is a hydrogenated polybutadiene and in which an unsaturated bond (e.g., a double bond between carbon atoms) of the polybutadiene is hydrogenated, and does not have an unsaturated bond (e.g., a double bond between carbon atoms) in a main chain and a side chain. For example, A-3 as a polybutadiene is a polybutadiene according to Comparative Example.

A-4 as a polybutadiene is a urethane acrylate-terminated hydrogenated polybutadiene and includes a polybutadiene but is terminated with a urethane acrylate. In one or more embodiments, A-4 as a polybutadiene includes a radical curable group. A-5 as a polybutadiene includes a polybutadiene but is terminated with a urethane acrylate. For example, A-4 and A-5 as polybutadienes are polybutadienes according to Comparative Examples.

In Table 1, each of Examples 1 to 3 is a resin composition according to one or more embodiments. Each of Examples 1 to 3 includes a polybutadiene having an unsaturated bond (e.g., a double bond between carbon atoms) in at least one selected from among a main chain and a side chain, a photoinitiator, a monofunctional (meth)acrylate monomer, and a (meth)acrylate oligomer. Each of the resin compositions according to Examples 1 to 3 includes about 1 wt % or more and less than about 10 wt % of the polybutadiene based on a total of 100 wt % of the resin composition. Each of the resin compositions according to Examples 1 to 3 includes about 82 wt % or more and less than about 92 wt % of the monofunctional (meth)acrylate monomer based on a total of 100 wt % of the resin composition.

In one or more embodiments, each of resin compositions according to Comparative Examples 4 and 5 does not include a polybutadiene. A resin composition according to Comparative Example 6 includes a polybutadiene, but A-3 included in the resin composition according to Comparative Example 6 is a polybutadiene that does not have unsaturated bonds (e.g., double bonds between carbon atoms) in a main chain and a side chain.

A resin composition according to Comparative Example 7 includes a polybutadiene, but includes 14 g of the polybutadiene with respect to a total weight of 105 g of the resin composition. The resin composition according to Comparative Example 7 includes about 13.3 wt % of the polybutadiene based on a total of 100 wt % of the resin composition. The resin composition according to Comparative Example 7 does not satisfy (e.g., is not within) the weight range (e.g., about 1 wt % or more and less than about 10 wt %) of the polybutadiene according to one or more embodiments. Each of resin compositions according to Comparative Examples 8 and 9 includes a urethane acrylate-terminated polybutadiene unlike the resin composition according to one or more embodiments.

Referring to Table 1, it may be seen that the resin compositions according to Examples and Comparative Examples each have a shear viscosity of about 8 mPa·s to about 50 mPa·s as measured at a temperature of about 25° C. according to JIS Z8803 method. In one or more embodiments, it may be ascertained that the resin compositions according to Examples and Comparative Examples are suitable to be provided by an inkjet printing method and/or a dispensing method.

### 2. Evaluation of Adhesive Members

Table 2 below shows results of evaluating 180° peel strengths, tensile moduli, and yellow indexes of adhesive members made or provided from each of the resin compositions according to Examples and Comparative Examples. The adhesive members according to Examples E-1 to E-3 were made or provided from the resin compositions according to Examples 1 to 3, respectively. The adhesive members according to Comparative Examples B-1 to B-6 were made or provided from the resin compositions according to Comparative Examples 4 to 9, respectively. Hereinafter, the evaluation method will be described in more detail.

### 180° Peel Strength Measurement for Adhesive Members

Each of the resin compositions according to Examples and Comparative Examples was applied using an inkjet device in a thickness of about 50 μm onto soda-lime glass (product by Central Glass Co., Ltd.) having a size of about 26 mm×about 76 mm. Device Printer-CX (product by Microjet Technology Co., Ltd.) attached with (or coupled to) Km1024i (product by Konica Minolta Inc.) was used as the inkjet device. Ultraviolet light was emitted onto the soda-lime glass coated with the resin composition by using UV-LED lamps having peaks at wavelengths of about 365 nm and about 395 nm so that provided amounts of the light reach about 800 mJ/cm² and about 400 mJ/cm², respectively. Then, a PET film (thickness: about 50 μm, product by TOYOBO Co., Ltd., product name: A4360) having a size of about 20 mm×about 150 mm was bonded by applying a bonding pressure of about 0.15 MPa. The resin composition was cured to obtain a sample by emitting the ultraviolet light from a side of the PET film by using the UV-LED lamp having the peak at the wavelength of about 395 nm after the bonding so that a provided amount of the light reaches about 4,000 mJ/cm².

The measurement of the peel strength was performed three times on the obtained sample at a temperature of about 25° C., at a speed of about 300 mm/min by using a universal testing machine (product by Instron Corporation, 5965 type or kind) so that a peel angle is about 180°. Average values for about 50 mm peeling were obtained, and the peel strength per width of about 25 mm obtained by multiplying each of the obtained values by about 1.25 was recorded in Table 2.

### Tensile Modulus Measurement for Adhesive Members

A release-treated PET film (product by PANAC Co., Ltd., product name: NP 100A) and a silicone rubber sheet (product by Tigers Polymer Co., Ltd.) were stacked in sequence on slide glass (product by Matsunami Glass Ltd., product name: S1112). The silicone rubber sheet was cut to have a hole size corresponding to a size 8 dumbbell. Each of the resin compositions according to Examples and Comparative Examples was dropped into the hole of the silicone rubber sheet and irradiated with ultraviolet light by using UV-LED lamps having peaks at wavelengths of about 405 nm and about 365 nm so that provided amounts of the light reach about 800 mJ/cm² and about 400 mJ/cm², respectively. Thereafter, the release film was bonded to the resin composition, and then the resin composition was irradiated with ultraviolet light using a UV-LED lamp having a peak at a wavelength of about 395 nm so that a provided amount of the light reaches about 4,000 mJ/cm², thereby obtaining a sample.

The tensile modulus measurement was performed on the obtained samples using a dynamic viscoelasticity measurement device, RSA-G2 (product by TA Instruments) at a frequency of about 1 Hz and at a temperature of about 25° C.

### Yellow Index Measurement for Adhesive Members

Each of the resin compositions according to Examples and Comparative Examples was provided between slide glass (product by Matsunami Glass Ltd., product name: S1112) attached with (or coupled to) a spacer having a thickness of about 200 μm. Ultraviolet light was emitted using UV-LED lamps having peaks at wavelengths of about 405 nm and about 365 nm so that provided amounts of the light reach about 800 mJ/cm² and about 400 mJ/cm², respectively. Thereafter, the resin composition was cured to obtain a sample by emitting ultraviolet light using a UV-LED lamp having a peak at a wavelength of about 395 nm so that a provided amount of the light reaches about 4,000 mJ/cm².

A light fastness test was performed on the obtained samples, and the yellow indexes were measured using a spectrophotometer, COH7700 (product by NIPPON DENSHOKU INDUSTRIES Co., Ltd.) before and after the light fastness test. The light fastness test was performed by emitting ultraviolet light having a wavelength of about 280 nm to about 3,000 nm in an intensity of a total of about 1120 W/m for about 80 hours according to DIN 75220 method.

TABLE 2

| | | | | Compar. | Compar. | Compar. | Compar. | Compar. | Compar. |
|---|---|---|---|---|---|---|---|---|---|
| | Example | Example | Example | Example | Example | Example | Example | Example | Example |
| | E-1 | E-2 | E-3 | B-1 | B-2 | B-3 | B-4 | B-5 | B-6 |
| 180° peel | 1600 | 1200 | 550 | 10 | 60 | 350 | 100 | 200 | 150 |
| strength | | | | | | | | | |
| (25° C., | | | | | | | | | |
| gf/25 mm) | | | | | | | | | |
| Tensile | 40 | 62 | 620 | 75 | 1010 | 30 | 30 | 45 | 50 |
| modulus | | | | | | | | | |
| (25° C., | | | | | | | | | |
| MPa) | | | | | | | | | |
| Yellow | 0.6 | 0.6 | 0.7 | 1.5 | 1.3 | 2.1 | 2.3 | 1.7 | 1.2 |
| index (YI) | | | | | | | | | |

Referring to Table 2, it may be seen that each of the adhesive members according to Examples E-1 to E-3 has the 180° peel strength of about 500 gf/25 mm or more for at least one selected from among a glass substrate and a polymer substrate at a temperature of about 25° C. It may be seen that each of the adhesive members according to Examples E-1 to E-3 has the tensile modulus of about 10 MPa to about 900 MPa at the temperature of about 25° C. It may be seen that each of the adhesive members according to Examples E-1 to E-3 has the yellow index of about 1 or less after the light fastness test according to DIN75220 method. For example, it may be ascertained that the adhesive members according to Examples E-1 to E-3 satisfy the 180° peel strength, the tensile modulus, and the yellow index according to one or more embodiments. As described above, the adhesive members according to Examples E-1 to E-3 were made or provided from the resin compositions according to Examples 1 to 3, respectively, and correspond to adhesive members according to one or more embodiments. Thus, it may be ascertained that the adhesive member made or provided from the resin composition according to one or more embodiments would exhibit excellent or suitable reliability of adhesion, excellent or suitable impact resistance, and excellent or suitable light fastness.

Each of the adhesive members according to Comparative Examples B-1 and B-3 has the 180° peel strength of less than about 500 gf/25 mm for the glass substrate and the polymer substrate at the temperature of about 25° C. Each of the adhesive members according to Comparative Examples B-1 and B-3 has the yellow index of more than about 1 after the light fastness test according to DIN75220 method. For example, the adhesive members according to Comparative Examples B-1 and B-3 do not satisfy the 180° peel strength and the yellow index according to one or more embodiments. As described above, the adhesive members according to Comparative Examples B-1 and B-3 were made or provided from the resin compositions according to Comparative Examples 4 and 6, respectively. The adhesive member according to Comparative Example B-1 was made or provided from the resin composition according to Comparative Example 4, which does not include the polybutadiene. The adhesive member according to Comparative Example B-3 was made or provided from the resin composition according to Comparative Example 6 including a polybutadiene, but the polybutadiene does not include unsaturated bonds (e.g., double bonds between carbon atoms) in the main chain and the side chain. In one or more embodiments, the adhesive members according to Comparative Examples B-1 and B-3 exhibit low adhesion and low light fastness.

The adhesive member according to Comparative Example B-2 has the 180° peel strength of less than about 500 gf/25 mm for the glass substrate and the polymer substrate at the temperature of about 25° C., and has the tensile modulus of more than about 900 MPa at the temperature of about 25° C. The adhesive member according to Comparative Example B-2 has the yellow index of more than about 1 after the light fastness test according to DIN75220 method. For example, the adhesive member according to Comparative Example B-2 does not satisfy the 180° peel strength, the tensile modulus, and the yellow index according to one or more embodiments. As described above, the adhesive member according to Comparative Example B-2 was made or provided from the resin composition according to Comparative Example 5, and the resin composition according to Comparative Example 5 does not include the polybutadiene. In one or more embodiments, the adhesive member according to Comparative Example B-2 exhibits low adhesion, low light fastness, and low impact resistance.

The adhesive member according to Comparative Example B-4 has the 180° peel strength of less than about 500 gf/25 mm for the glass substrate and the polymer substrate at the temperature of about 25° C., and has the yellow index of more than about 1 after the light fastness test according to DIN75220 method. For example, the adhesive member according to Comparative Example B-4 does not satisfy the 180° peel strength and the yellow index according to one or more embodiments. As described above, the adhesive member according to Comparative Example B-4 was made or provided from the resin composition according to Comparative Example 7, and the resin composition according to Comparative Example 7 includes about 10 wt % or more of the polybutadiene. In one or more embodiments, the adhesive member according to Comparative Example B-4 exhibit low adhesion and low light fastness.

Each of the adhesive members according to Comparative Examples B-5 and B-6 has the 180° peel strength of less than about 500 gf/25 mm for the glass substrate and the polymer substrate at the temperature of about 25° C., and has the yellow index of more than about 1 after the light fastness test according to DIN75220 method. For example, each of the adhesive members according to Comparative Examples B-5 and B-6 does not satisfy the 180° peel strength and the yellow index according to one or more embodiments. As described above, the adhesive members according to Comparative Examples B-5 and B-6 were made or provided from the resin compositions according to Comparative Examples 8 and 9, respectively, and the resin compositions according to Comparative Examples 8 and 9 each include the urethane acrylate-terminated polybutadiene. In one or more embodiments, the adhesive members according to Comparative Examples B-5 and B-6 exhibit low adhesion and low light fastness.

In one or more embodiments, a display device (e.g., an electronic device) may include an adhesive member between a display panel and a window. The adhesive member may be provided by photocuring a resin composition according to one or more embodiments. The resin composition according to one or more embodiments may include a polybutadiene having an unsaturated bond (e.g., a double bond between carbon atoms) in at least one selected from among a main chain and a side chain, a photoinitiator, a monofunctional (meth)acrylate monomer, and/or a (meth)acrylate oligomer. An amount of the polybutadiene may be about 1 wt % or more and less than about 10 wt % based on a total of 100 wt % of the resin composition. In one or more embodiments, the resin composition may exhibit a low-viscosity characteristic before curing and exhibit excellent or suitable reliability of adhesion, excellent or suitable impact resistance, and/or excellent or suitable light fastness after the curing.

The resin composition according to one or more embodiments may include the polybutadiene to exhibit the low-viscosity characteristic before the curing and/or exhibit the excellent or suitable impact resistance, the excellent or suitable reliability of adhesion, and/or the excellent or suitable light fastness after the curing.

The adhesive member according to one or more embodiments may be made or provided from the resin composition according to one or more embodiments to exhibit the excellent or suitable impact resistance, the excellent or suitable reliability of adhesion, and/or the excellent or suitable light fastness.

The display device according to one or more embodiments may include the adhesive member according to one or more embodiments to exhibit the excellent or suitable reliability.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed.

Therefore, the technical scope of the present disclosure should not be limited to one or more embodiments and/or examples, but should be determined by the appended claims and the equivalents thereof of the present disclosure.

What is claimed is:

1. A resin composition, comprising:
a polybutadiene having an unsaturated bond in at least one selected from among a main chain and a side chain, at least one photoinitiator, at least one monofunctional (meth)acrylate monomer, and at least one (meth)acrylate oligomer,
wherein the resin composition does not comprise a urethane (meth)acrylate-terminated polybutadiene,
wherein an amount of the polybutadiene is about 1 wt % or more and less than about 10 wt % based on a total of 100 wt % of the resin composition,
wherein the resin composition has a shear viscosity of about 8 mPa·s to about 50 mPa·s as measured at a temperature of about 25° C. according to JIS Z8803 method, and
wherein the resin composition has a tensile modulus of about 10 MPa to about 900 MPa at a temperature of about 25° C. after photocuring.

2. The resin composition as claimed in claim 1, wherein the resin composition has a 180° peel strength of about 500 gf/25 mm or more for at least one selected from among a glass substrate and a polymer substrate at the temperature of about 25° C. after the photocuring.

3. The resin composition as claimed in claim 1, wherein the resin composition has a yellow index (YI) of about 1 or less after a light fastness test according to DIN75220 method after the photocuring.

4. The resin composition as claimed in claim 1, wherein the polybutadiene comprises a moiety represented by Formula 1:

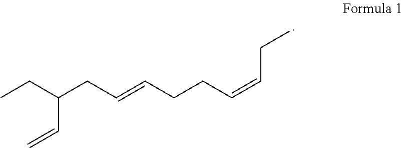

5. The resin composition as claimed in claim 1, wherein the monofunctional (meth)acrylate monomer comprises at least one selected from among 4-hydroxybutyl acrylate (4-HBA), isobornyl acrylate (IBXA), and isodecyl acrylate (IDAA).

6. The resin composition as claimed in claim 1, wherein an amount of the monofunctional (meth)acrylate monomer is about 82 wt % or more and less than about 92 wt % based on a total of 100 wt % of the resin composition.

7. The resin composition as claimed in claim 1, wherein the photoinitiator comprises a radical polymerization initiator.

8. The resin composition as claimed in claim 1, wherein the resin composition is provided by an inkjet printing method or a dispensing method.

9. An adhesive member, comprising:
a polymer derived from a resin composition and having a tensile modulus of about 10 MPa to about 900 MPa at a temperature of about 25° C.,
wherein the resin composition comprises a polybutadiene having an unsaturated bond in at least one selected from among a main chain and a side chain, at least one photoinitiator, at least one monofunctional (meth)acrylate monomer, and at least one (meth)acrylate oligomer,
wherein the resin composition does not comprise a urethane (meth)acrylate-terminated polybutadiene,
wherein an amount of the polybutadiene is about 1 wt % or more and less than about 10 wt % based on a total of 100 wt % of the resin composition, and
wherein the resin composition has a shear viscosity of about 8 mPa·s to about 50 mPa·s as measured at a temperature of about 25° C. according to JIS Z8803 method.

10. The adhesive member as claimed in claim 9, wherein the adhesive member has a 180° peel strength of about 500 gf/25 mm or more for at least one selected from among a glass substrate and a polymer substrate at the temperature of about 25° C.

11. The adhesive member as claimed in claim 9, wherein the adhesive member has a yellow index (YI) of about 1 or less after a light fastness test according to DIN 75220 method.

12. The adhesive member as claimed in claim 9, wherein the polybutadiene comprises a moiety represented by Formula 1:

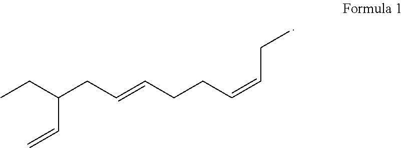

13. The adhesive member as claimed in claim 9, wherein the monofunctional (meth)acrylate monomer comprises at least one selected from among 4-hydroxybutyl acrylate (4-HBA), isobornyl acrylate (IBXA), and isodecyl acrylate (IDAA).

14. An electronic device comprising:
a display panel;
a window on the display panel; and
an adhesive member,
wherein the adhesive member comprises a polymer derived from a resin composition having a shear viscosity of about 8 mPa·s to about 50 mPa·s as measured at a temperature of about 25° C. according to JIS Z8803 method and is between the display panel and the window,
wherein the adhesive member has a tensile modulus of about 10 MPa to about 900 MPa at a temperature of about 25° C.,
wherein the resin composition comprises a polybutadiene having an unsaturated bond in at least one selected from among a main chain and a side chain, at least one photoinitiator, at least one monofunctional (meth)acrylate monomer, and at least one (meth)acrylate oligomer,
wherein the resin composition does not comprise a urethane (meth)acrylate-terminated polybutadiene, and
wherein an amount of the polybutadiene is about 1 wt % or more and less than about 10 wt % based on a total of 100 wt % of the resin composition.

15. The electronic device as claimed in claim 14, wherein the adhesive member has a 180° peel strength of about 500 gf/25 mm or more for at least one selected from among a glass substrate and a polymer substrate at the temperature of about 25° C.

16. The electronic device as claimed in claim 14, wherein the adhesive member has a yellow index (YI) of about 1 or less after a light fastness test according to DIN 75220 method.

17. The electronic device as claimed in claim 14, wherein the monofunctional (meth)acrylate monomer comprises at least one selected from among 4-hydroxybutyl acrylate (4-HBA), isobornyl acrylate (IBXA), and isodecyl acrylate (IDAA).

18. The electronic device as claimed in claim 14, wherein the display panel is foldable around at least one folding axis.

19. The electronic device as claimed in claim 14, further comprising:
a light control layer between the adhesive member and the window; and
an optical adhesive layer between the light control layer and the window,
wherein the optical adhesive layer comprises the polymer derived from the resin composition.

20. The electronic device as claimed in claim 14, further comprising:
an input sensing part between the display panel and the window,
wherein the adhesive member is between the display panel and the input sensing part or between the input sensing part and the window.
